(19) United States
(12) Patent Application Publication
(10) Pub. No.: US 2026/0105207 A1
(43) Pub. Date: Apr. 16, 2026

(54) BUILDING EQUIPMENT CONSTRUCTION TOOL WITH GENERATIVE AI-BASED SYNTHESIS OF DESIGN COLLATERAL

(71) Applicant: Tyco Fire & Security GmbH, Neuhausen am Rheinfall (CH)

(72) Inventors: Joseph Karl Gress, New Berlin, WI (US); Michael A. Capille, Boca Raton, FL (US); Heather Crynes, Lake Worth, FL (US); Nicholas I. Hull, Etters, PA (US); Gustavo Adolfo Banguera Delgado, Tierralta (CO); Jorge Antonio Corral Akle, Parkland, FL (US); Dale S. Smith, Parkville, MD (US); Isaac J. Krull, Glendale, WI (US); Christopher Ryan Felpel, York, PA (US); Jagadeesh Guntimadugu, Schaffhausen (CH); Brian S. Smith, York, PA (US)

(73) Assignee: Tyco Fire & Security GmbH, Neuhausen am Rheinfall (CH)

(21) Appl. No.: 19/355,735

(22) Filed: Oct. 10, 2025

Related U.S. Application Data
(60) Provisional application No. 63/706,543, filed on Oct. 11, 2024.

(51) Int. Cl. G06F 30/13; G06F 30/27

(52) U.S. Cl. CPC G06F 30/13; G06F 30/27

(57) ABSTRACT

A building equipment construction system includes a simulation engine configured to generate first basis of design (BOD) collateral including first simulated building equipment performance ratings based on first user requests comprising first building equipment operating requirements. The system includes an artificial intelligence (AI) model trained on the first user requests and the first BOD collateral and configured to generate second BOD collateral including second building equipment performance ratings based on a second user request including second building equipment operating requirements. The second BOD collateral is used to construct building equipment satisfying the second building equipment operating requirements.

### CROSS-REFERENCE TO RELATED PATENT APPLICATIONS

This application claims the benefit of and priority to U.S. Provisional Application No. 63/706,543, filed Oct. 11, 2024, which is incorporated by reference herein in its entirety.

### BACKGROUND

The present disclosure relates generally to building equipment (e.g., HVAC equipment) operable to monitor and control various building conditions and more particularly to systems and methods for simulating building equipment performance under a variety of operating conditions and equipment configurations. The present disclosure further relates to systems and methods for training and using AI models for simulating building equipment performance.

Conventional approaches to simulating building equipment performance require running complex and time-intensive simulations to generate comprehensive equipment item models, simulating the performance of the equipment items under various operating conditions, and generating design collateral based on the simulated performance of the equipment items. Generating equipment models requires a high level of accuracy in the models'depictions of the equipment item and is prone to human-error due to the required high level of accuracy. Accurately simulating the performance of the equipment items under various operating conditions requires all the operating conditions to be known, however the process of determining all the operating conditions is a time-consuming process and it is probable that one or more operating conditions will not be determined in this process. These compounding factors make current methods highly susceptible to inaccurate and/or incomplete simulations and thus highly susceptible to producing inaccurate and/or incomplete design collateral.

### SUMMARY

One implementation of the present disclosure is a method comprising executing a simulation engine to generate a first BOD collateral comprising first simulated building equipment performance ratings based on first user requests comprising first building equipment operating requirements. The method then trains an artificial intelligence (AI) model using the first user requests and the first BOD collateral as training data. The method then executing the AI model to generate a second BOD collateral comprising second building equipment performance ratings based on a second user request comprising first building equipment operating requirements. The method then using the second BOD collateral to construct building equipment satisfying the second building equipment operating requirements. In some embodiments the artificial intelligence model is also trained on documentation regarding one or more equipment items.

In some embodiments, the first BOD collateral and the second BOD collateral as described in the method include at least one of bill of material (BOM) data, unit and wiring diagrams, unit specification text, or warranties. In some embodiments, the AI model may be run in lieu of the simulation engine. Determining whether to execute the simulation engine or bypass the simulation engine when generating the second BOD collateral may be based on a similarity between the second user request and one or more of the first user requests. In some embodiments, generating the second BOD collateral by bypassing the simulation engine and reusing or modifying a portion of the first BOD collateral may be in response to the similarity exceeding a threshold. In some embodiments, generating the second BOD collateral by executing the simulation engine and discarding the first BOD collateral in response to the similarity not exceeding a threshold.

In some embodiments, evaluating the similarity may be by comparing the second building equipment operating requirements of the second user request with the first building equipment operating requirements of the one or more of the first user requests. In some embodiments, evaluating the similarity may be by comparing a first version of the simulation engine used to generate the first BOD collateral with a second version of the simulation engine available upon receipt of the second user request.

Another implementation of the present disclosure is a system comprising a simulation engine configured to generate a first BOD collateral comprising first simulated building equipment performance ratings based on first user requests comprising first building equipment operating requirements. The system also comprising an artificial intelligence (AI) model trained on the first user requests and the first BOD collateral and configured to generate second BOD collateral comprising second building equipment performance ratings based on a second user request comprising second building equipment operating requirements, wherein the second BOD collateral is used to construct building equipment satisfying the second building equipment operating requirements. In some embodiments, the first BOD collateral and the second BOD collateral may further comprise at least one of bill of material (BOM) data, unit and wiring diagrams, unit specification text, or warranties.

In some embodiments, the AI model may be configured to determine whether to execute the simulation engine or bypass the simulation engine when generating the second BOD collateral based on a similarity between the second user request and one or more of the first user requests. In some embodiments, the AI model may be configured to generate the second BOD collateral by bypassing the simulation engine and reusing or modifying a portion of the first BOD collateral in response to the similarity exceeding a threshold. In some embodiments, the AI model may be configured to generate the second BOD collateral by executing the simulation engine and discarding the first BOD collateral in response to the similarity not exceeding a threshold. In some embodiments, the AI model may be configured to evaluate the similarity by comparing the second building equipment operating requirements of the second user request with the first building equipment operating requirements of the one or more of the first user requests. In some embodiments, the AI model may be configured to evaluate the similarity by comparing a first version of the simulation engine used to generate the first BOD collateral with a second version of the simulation engine available upon receipt of the second user request.

Another implementation of the present disclosure is a system comprising one or more non-transitory computer-readable media storing instructions that, when executed by one or more processors, cause the one or more processors to perform operations. The operations may include executing a simulation engine to generate a first BOD collateral comprising first simulated building equipment performance ratings based on first user requests comprising first building equipment operating requirements. The operations may also include training an AI model using the first user requests and the first BOD collateral as training data. The operations may also include executing the AI model to generate a second BOD collateral comprising second building equipment performance ratings based on a second user request comprising second building equipment operating requirements. The operations may also include using the second BOD collateral to construct building equipment satisfying the second building equipment operating requirements.

In some embodiments, the one or more non-transitory computer readable media may include the first BOD collateral and the second BOD collateral where they may further comprise at least one of bill of material (BOM) data, unit and wiring diagrams, unit specification text, or warranties. In some embodiments, the one or more non-transitory computer readable media may include the operations comprising determining whether to execute the simulation engine or bypass the simulation engine when generating the second BOD collateral based on a similarity between the second user request and one or more of the first user requests. In some embodiments, the one or more non-transitory computer readable media may include the operations comprising generating the second BOD collateral by bypassing the simulation engine and reusing or modifying a portion of the first BOD collateral in response to the similarity exceeding a threshold. In some embodiments, the one or more non-transitory computer readable media may include operations comprising generating the second BOD collateral by executing the simulation engine and discarding the first BOD collateral in response to the similarity not exceeding a threshold. In some embodiments, the one or more non-transitory computer readable media may include the operations including evaluating the similarity threshold by comparing one of the second building equipment operating requirements of the second user request with the first building equipment operating requirements of the one or more of the first user requests, or a first version of the simulation engine used to generate the first BOD collateral with a second version of the simulation engine available upon receipt of the second user request.

### BRIEF DESCRIPTION OF THE DRAWINGS

Various objects, aspects, features, and advantages of the disclosure will become more apparent and better understood by referring to the detailed description taken in conjunction with the accompanying drawings, in which like reference characters identify corresponding elements throughout. In the drawings, like reference numbers generally indicate identical, functionally similar, and/or structurally similar elements.

FIG. 1 is a drawing of a building equipped with a building management system (BMS) and a HVAC system, according to some embodiments.

FIG. 2 is a schematic of a waterside system which can be used as part of the HVAC system of FIG. 1, according to some embodiments.

FIG. 3 is a block diagram of an airside system which can be used as part of the HVAC system of FIG. 1, according to some embodiments.

FIG. 4 is a block diagram of a BMS which can be used in the building of FIG. 1, according to some embodiments.

FIG. 5 is another block diagram of a BMS which can be used in the building of FIG. 1, according to some embodiments.

FIG. 6 is a flow chart of a process of a simulation engine taking user RFQ documents and generating a BOD collateral on that information, according to an exemplary embodiment.

FIG. 7 is a block diagram of a system for a generating platform to communicate with a user interface and a network, according to an exemplary embodiment.

FIG. 8 is a block diagram of the generating platform of FIG. 7 for training a generative AI model using simulated data generated by a simulation engine, according to an exemplary embodiment.

FIG. 9 is a flow chart of a process of the generating platform of FIG. 7 training the AI model, according to an exemplary embodiment.

FIG. 10 is a flow chart of a process of implementing the trained AI model of FIG. 7 to generate basis of design collaterals based on the configuration dataset, according to an exemplary embodiment.

FIG. 11 is a product drawing of a water-cooled chiller which can be generated as a type of BOD collateral by the generating platform of FIG. 7, according to an exemplary embodiment.

FIG. 12 is a product drawing of the water-cooled chiller of FIG. 11 which can be generated as a type of BOD collateral by the generating platform of FIG. 7, according to an exemplary embodiment.

FIG. 13 is a wiring drawing of a grounding variable speed drive which can be generated as a type of BOD collateral by the generating platform of FIG. 7, according to an exemplary embodiment.

FIG. 14 is a drawing of a variable speed drive which can be generated as a type of BOD collateral by the generating platform of FIG. 7, according to an exemplary embodiment.

FIG. 15A and FIG. 15B are drawings of field connections which can be generated as a type of BOD collateral by the generating platform of FIG. 7, according to an exemplary embodiment.

FIG. 16 is a flow chart of a process of the generating platform of FIG. 7 training and executing the AI model, according to an exemplary embodiment.

### DETAILED DESCRIPTION

### Overview

Referring generally to the FIGURES, a building equipment construction tool with generative artificial intelligence-based synthesis of design collateral is shown, according to various embodiments. The building equipment construction tool may include several components including a selection tool and a scanning and extraction tool. The selection tool may be configured for simulating building equipment operation. An AI interpreter can take input data (e.g., temperatures, flows, height, width and length limitations, etc.) from a user device according to an exemplary embodiment. The AI interpreter interprets and converts the data into configuration data for an AI orchestrator. The AI orchestrator takes the configuration data and communicates with a storage system along with a BOD collateral database (continually populated with proprietary data) to determine if there is an exact BOD collateral already existing for the needs of the current system. In an exemplary embodiment, there is an exact match for a BOD collateral and the timely simulation engine is bypassed to give the resulting BOD collateral efficiently. An AI model is also trained on the BOD collateral database data along with creating training data with the simulation engine by simulating equipment items to generate a first BOD collateral passed to the AI model. In an exemplary embodiment, the ratings engine is up to date used to train the AI model and the trained AI model determines a BOD collateral based on the input data which is greater than or equal to a threshold. The BOD collateral is efficiently returned without needing to run the simulation for each configuration. In an exemplary embodiment, the AI orchestrator did not find an exact match, and the trained AI did not create a BOD collateral that was greater than or equal to a threshold for equivalency, so the lengthy simulation engine must be run to create a BOD collateral for the input.

### Building HVAC Systems and Building Management Systems

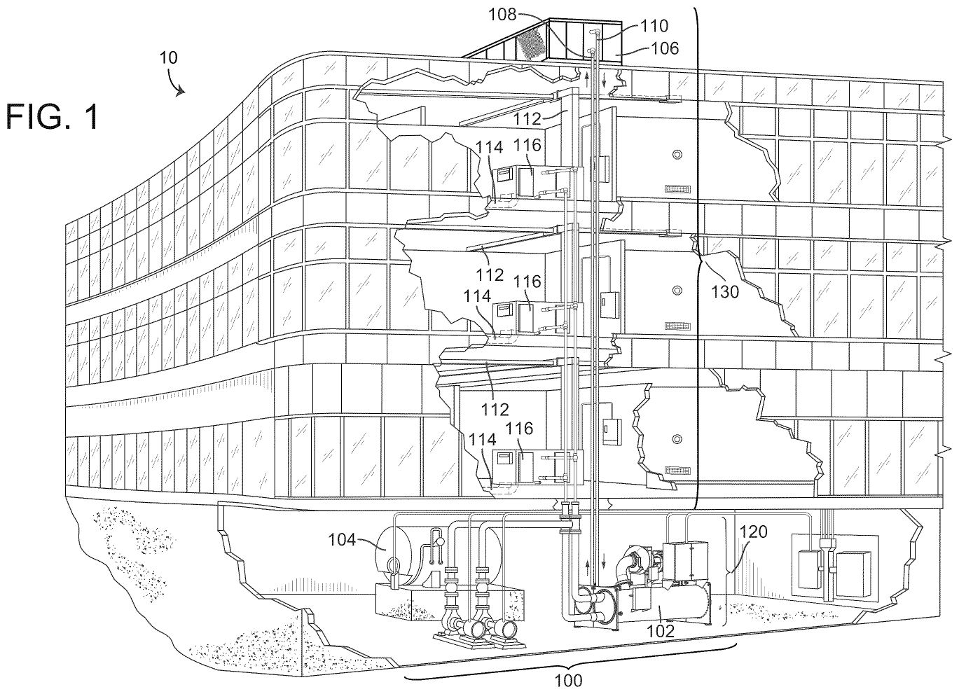

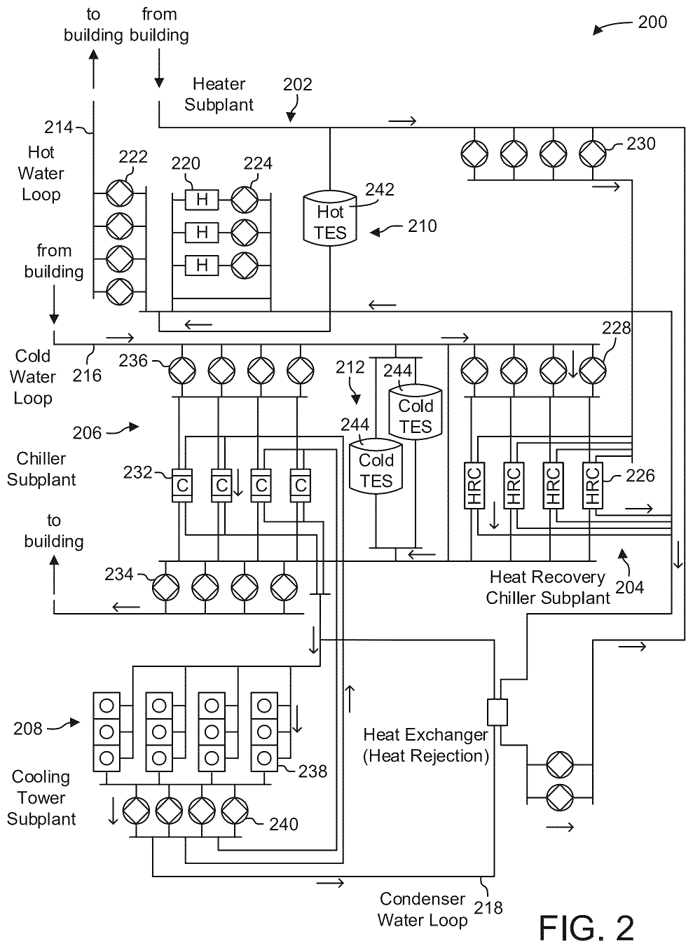

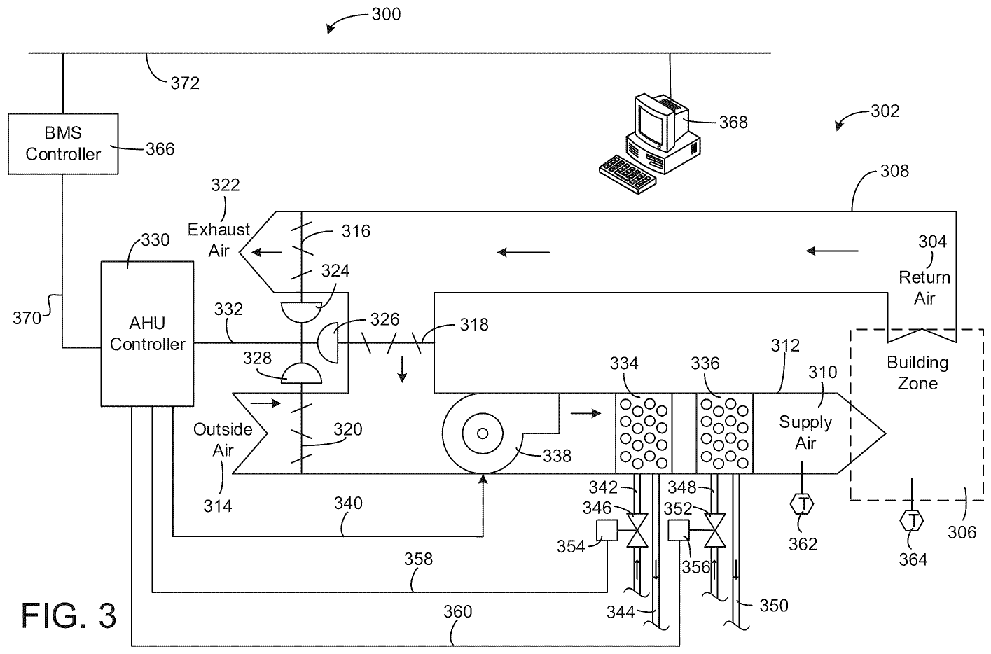

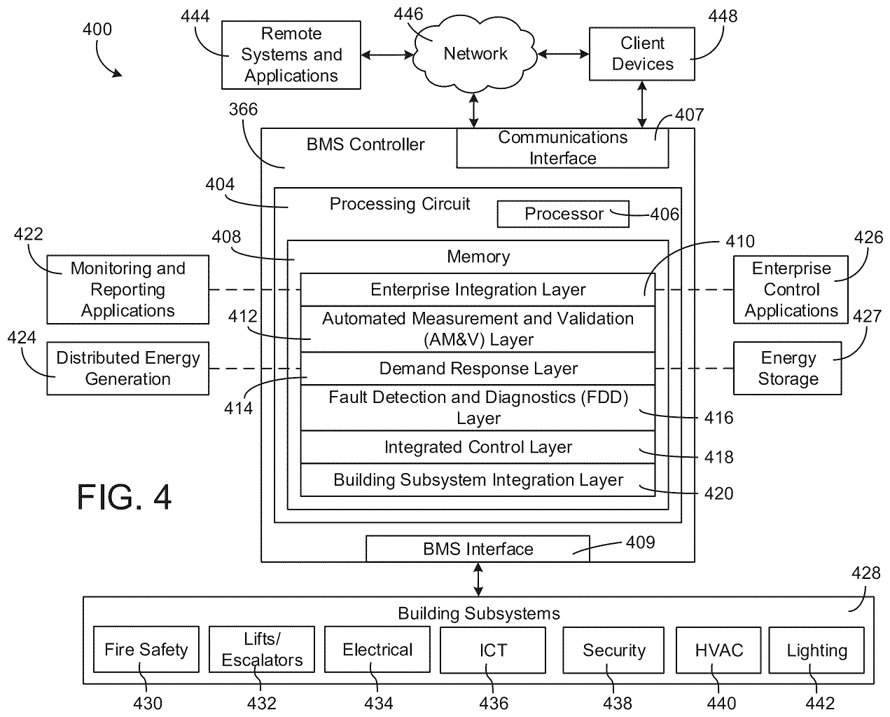

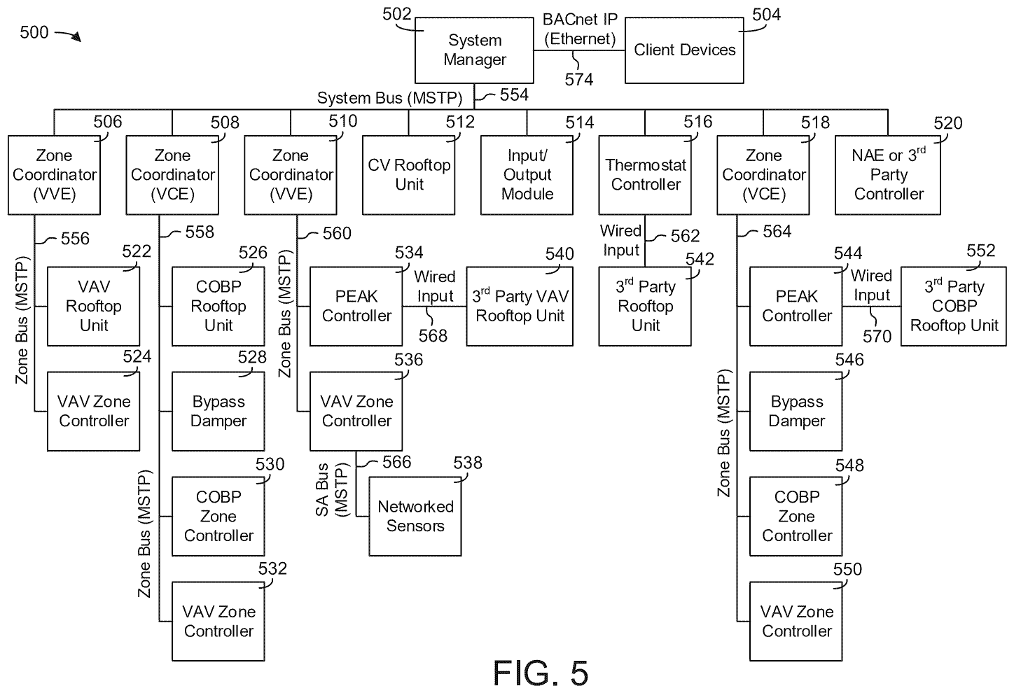

Referring now to FIGS. 1-5, several building management systems (BMS) and HVAC systems in which the systems and methods of the present disclosure can be implemented are shown, according to some embodiments. In brief overview, FIG. 1 shows a building 10 equipped with a HVAC system 100. FIG. 2 is a block diagram of a waterside system 200 which can be used to serve building 10. FIG. 3 is a block diagram of an airside system 300 which can be used to serve building 10. FIG. 4 is a block diagram of a BMS which can be used to monitor and control building 10. FIG. 5 is a block diagram of another BMS which can be used to monitor and control building 10.

### Building and HVAC System

Referring particularly to FIG. 1, a perspective view of a building 10 is shown. Building 10 is served by a BMS. A BMS is, in general, a system of devices configured to control, monitor, and manage equipment in or around a building or building area. A BMS can include, for example, a HVAC system, a security system, a lighting system, a fire alerting system, any other system that is capable of managing building functions or devices, or any combination thereof.

The BMS that serves building 10 includes a HVAC system 100. HVAC system 100 can include a plurality of HVAC devices (e.g., heaters, chillers, air handling units, pumps, fans, thermal energy storage, etc.) configured to provide heating, cooling, ventilation, or other services for building 10. For example, HVAC system 100 is shown to include a waterside system 120 and an airside system 130. Waterside system 120 may provide a heated or chilled fluid to an air handling unit of airside system 130. Airside system 130 may use the heated or chilled fluid to heat or cool an airflow provided to building 10. An exemplary waterside system and airside system which can be used in HVAC system 100 are described in greater detail with reference to FIGS. 2-3.

HVAC system 100 is shown to include a chiller 102, a boiler 104, and a rooftop air handling unit (AHU) 106. Waterside system 120 may use boiler 104 and chiller 102 to heat or cool a working fluid (e.g., water, glycol, etc.) and may circulate the working fluid to AHU 106. In various embodiments, the HVAC devices of waterside system 120 can be located in or around building 10 (as shown in FIG. 1) or at an offsite location such as a central plant (e.g., a chiller plant, a steam plant, a heat plant, etc.). The working fluid can be heated in boiler 104 or cooled in chiller 102, depending on whether heating or cooling is required in building 10. Boiler 104 may add heat to the circulated fluid, for example, by burning a combustible material (e.g., natural gas) or using an electric heating element. Chiller 102 may place the circulated fluid in a heat exchange relationship with another fluid (e.g., a refrigerant) in a heat exchanger (e.g., an evaporator) to absorb heat from the circulated fluid. The working fluid from chiller 102 and/or boiler 104 can be transported to AHU 106 via piping 108.

AHU 106 may place the working fluid in a heat exchange relationship with an airflow passing through AHU 106 (e.g., via one or more stages of cooling coils and/or heating coils). The airflow can be, for example, outside air, return air from within building 10, or a combination of both. AHU 106 may transfer heat between the airflow and the working fluid to provide heating or cooling for the airflow. For example, AHU 106 can include one or more fans or blowers configured to pass the airflow over or through a heat exchanger containing the working fluid. The working fluid may then return to chiller 102 or boiler 104 via piping 110.

Airside system 130 may deliver the airflow supplied by AHU 106 (i.e., the supply airflow) to building 10 via air supply ducts 112 and may provide return air from building 10 to AHU 106 via air return ducts 114. In some embodiments, airside system 130 includes multiple variable air volume (VAV) units 116. For example, airside system 130 is shown to include a separate VAV unit 116 on each floor or zone of building 10. VAV units 116 can include dampers or other flow control elements that can be operated to control an amount of the supply airflow provided to individual zones of building 10. In other embodiments, airside system 130 delivers the supply airflow into one or more zones of building 10 (e.g., via supply ducts 112) without using intermediate VAV units 116 or other flow control elements. AHU 106 can include various sensors (e.g., temperature sensors, pressure sensors, etc.) configured to measure attributes of the supply airflow. AHU 106 may receive input from sensors located within AHU 106 and/or within the building zone and may adjust the flow rate, temperature, or other attributes of the supply airflow through AHU 106 to achieve setpoint conditions for the building zone.

### Waterside System

Referring now to FIG. 2, a block diagram of a waterside system 200 is shown, according to some embodiments. In various embodiments, waterside system 200 may supplement or replace waterside system 120 in HVAC system 100 or can be implemented separate from HVAC system 100. When implemented in HVAC system 100, waterside system 200 can include a subset of the HVAC devices in HVAC system 100 (e.g., boiler 104, chiller 102, pumps, valves, etc.) and may operate to supply a heated or chilled fluid to AHU 106. The HVAC devices of waterside system 200 can be located within building 10 (e.g., as components of waterside system 120) or at an offsite location such as a central plant.

In FIG. 2, waterside system 200 is shown as a central plant having a plurality of subplants 202-212. Subplants 202-212 are shown to include a heater subplant 202, a heat recovery chiller subplant 204, a chiller subplant 206, a cooling tower subplant 208, a hot thermal energy storage (TES) subplant 210, and a cold thermal energy storage (TES) subplant 212. Subplants 202-212 consume resources (e.g., water, natural gas, electricity, etc.) from utilities to serve thermal energy loads (e.g., hot water, cold water, heating, cooling, etc.) of a building or campus. For example, heater subplant 202 can be configured to heat water in a hot water loop 214 that circulates the hot water between heater subplant 202 and building 10. Chiller subplant 206 can be configured to chill water in a cold water loop 216 that circulates the cold water between chiller subplant 206 building 10. Heat recovery chiller subplant 204 can be configured to transfer heat from cold water loop 216 to hot water loop 214 to provide additional heating for the hot water and additional cooling for the cold water. Condenser water loop 218 may absorb heat from the cold water in chiller subplant 206 and reject the absorbed heat in cooling tower subplant 208 or transfer the absorbed heat to hot water loop 214. Hot TES subplant 210 and cold TES subplant 212 may store hot and cold thermal energy, respectively, for subsequent use.

Hot water loop 214 and cold water loop 216 may deliver the heated and/or chilled water to air handlers located on the rooftop of building 10 (e.g., AHU 106) or to individual floors or zones of building 10 (e.g., VAV units 116). The air handlers push air past heat exchangers (e.g., heating coils or cooling coils) through which the water flows to provide heating or cooling for the air. The heated or cooled air can be delivered to individual zones of building 10 to serve thermal energy loads of building 10. The water then returns to subplants 202-212 to receive further heating or cooling.

Although subplants 202-212 are shown and described as heating and cooling water for circulation to a building, it is understood that any other type of working fluid (e.g., glycol, CO2, etc.) can be used in place of or in addition to water to serve thermal energy loads. In other embodiments, subplants 202-212 may provide heating and/or cooling directly to the building or campus without requiring an intermediate heat transfer fluid. These and other variations to waterside system 200 are within the teachings of the present disclosure.

Each of subplants 202-212 can include a variety of equipment configured to facilitate the functions of the subplant. For example, heater subplant 202 is shown to include a plurality of heating elements 220 (e.g., boilers, electric heaters, etc.) configured to add heat to the hot water in hot water loop 214. Heater subplant 202 is also shown to include several pumps 222 and 224 configured to circulate the hot water in hot water loop 214 and to control the flow rate of the hot water through individual heating elements 220. Chiller subplant 206 is shown to include a plurality of chillers 232 configured to remove heat from the cold water in cold water loop 216. Chiller subplant 206 is also shown to include several pumps 234 and 236 configured to circulate the cold water in cold water loop 216 and to control the flow rate of the cold water through individual chillers 232.

Heat recovery chiller subplant 204 is shown to include a plurality of heat recovery heat exchangers 226 (e.g., refrigeration circuits) configured to transfer heat from cold water loop 216 to hot water loop 214. Heat recovery chiller subplant 204 is also shown to include several pumps 228 and 230 configured to circulate the hot water and/or cold water through heat recovery heat exchangers 226 and to control the flow rate of the water through individual heat recovery heat exchangers 226. Cooling tower subplant 208 is shown to include a plurality of cooling towers 238 configured to remove heat from the condenser water in condenser water loop 218. Cooling tower subplant 208 is also shown to include several pumps 240 configured to circulate the condenser water in condenser water loop 218 and to control the flow rate of the condenser water through individual cooling towers 238.

Hot TES subplant 210 is shown to include a hot TES tank 242 configured to store the hot water for later use. Hot TES subplant 210 may also include one or more pumps or valves configured to control the flow rate of the hot water into or out of hot TES tank 242. Cold TES subplant 212 is shown to include cold TES tanks 244 configured to store the cold water for later use. Cold TES subplant 212 may also include one or more pumps or valves configured to control the flow rate of the cold water into or out of cold TES tanks 244.

In some embodiments, one or more of the pumps in waterside system 200 (e.g., pumps 222, 224, 228, 230, 234, 236, and/or 240) or pipelines in waterside system 200 include an isolation valve associated therewith. Isolation valves can be integrated with the pumps or positioned upstream or downstream of the pumps to control the fluid flows in waterside system 200. In various embodiments, waterside system 200 can include more, fewer, or different types of devices and/or subplants based on the particular configuration of waterside system 200 and the types of loads served by waterside system 200.

### Airside System

Referring now to FIG. 3, a block diagram of an airside system 300 is shown, according to some embodiments. In various embodiments, airside system 300 may supplement or replace airside system 130 in HVAC system 100 or can be implemented separate from HVAC system 100. When implemented in HVAC system 100, airside system 300 can include a subset of the HVAC devices in HVAC system 100 (e.g., AHU 106, VAV units 116, ducts 112-114, fans, dampers, etc.) and can be located in or around building 10. Airside system 300 may operate to heat or cool an airflow provided to building 10 using a heated or chilled fluid provided by waterside system 200.

In FIG. 3, airside system 300 is shown to include an economizer-type air handling unit (AHU) 302. Economizer-type AHUs vary the amount of outside air and return air used by the air handling unit for heating or cooling. For example, AHU 302 may receive return air 304 from building zone 306 via return air duct 308 and may deliver supply air 310 to building zone 306 via supply air duct 312. In some embodiments, AHU 302 is a rooftop unit located on the roof of building 10 (e.g., AHU 106 as shown in FIG. 1) or otherwise positioned to receive both return air 304 and outside air 314. AHU 302 can be configured to operate exhaust air damper 316, mixing damper 318, and outside air damper 320 to control an amount of outside air 314 and return air 304 that combine to form supply air 310. Any return air 304 that does not pass through mixing damper 318 can be exhausted from AHU 302 through exhaust damper 316 as exhaust air 322.

Each of dampers 316-320 can be operated by an actuator. For example, exhaust air damper 316 can be operated by actuator 324, mixing damper 318 can be operated by actuator 326, and outside air damper 320 can be operated by actuator 328. Actuators 324-328 may communicate with an AHU controller 330 via a communications link 332. Actuators 324-328 may receive control signals from AHU controller 330 and may provide feedback signals to AHU controller 330. Feedback signals can include, for example, an indication of a current actuator or damper position, an amount of torque or force exerted by the actuator, diagnostic information (e.g., results of diagnostic tests performed by actuators 324-328), status information, commissioning information, configuration settings, calibration data, and/or other types of information or data that can be collected, stored, or used by actuators 324-328. AHU controller 330 can be an economizer controller configured to use one or more control algorithms (e.g., state-based algorithms, extremum seeking control (ESC) algorithms, proportional-integral (PI) control algorithms, proportional-integral-derivative (PID) control algorithms, model predictive control (MPC) algorithms, feedback control algorithms, etc.) to control actuators 324-328.

Still referring to FIG. 3, AHU 302 is shown to include a cooling coil 334, a heating coil 336, and a fan 338 positioned within supply air duct 312. Fan 338 can be configured to force supply air 310 through cooling coil 334 and/or heating coil 336 and provide supply air 310 to building zone 306. AHU controller 330 may communicate with fan 338 via communications link 340 to control a flow rate of supply air 310. In some embodiments, AHU controller 330 controls an amount of heating or cooling applied to supply air 310 by modulating a speed of fan 338.

Cooling coil 334 may receive a chilled fluid from waterside system 200 (e.g., from cold water loop 216) via piping 342 and may return the chilled fluid to waterside system 200 via piping 344. Valve 346 can be positioned along piping 342 or piping 344 to control a flow rate of the chilled fluid through cooling coil 334. In some embodiments, cooling coil 334 includes multiple stages of cooling coils that can be independently activated and deactivated (e.g., by AHU controller 330, by BMS controller 366, etc.) to modulate an amount of cooling applied to supply air 310.

Heating coil 336 may receive a heated fluid from waterside system 200 (e.g., from hot water loop 214) via piping 348 and may return the heated fluid to waterside system 200 via piping 350. Valve 352 can be positioned along piping 348 or piping 350 to control a flow rate of the heated fluid through heating coil 336. In some embodiments, heating coil 336 includes multiple stages of heating coils that can be independently activated and deactivated (e.g., by AHU controller 330, by BMS controller 366, etc.) to modulate an amount of heating applied to supply air 310.

Each of valves 346 and 352 can be controlled by an actuator. For example, valve 346 can be controlled by actuator 354 and valve 352 can be controlled by actuator 356. Actuators 354-356 may communicate with AHU controller 330 via communications links 358-360. Actuators 354-356 may receive control signals from AHU controller 330 and may provide feedback signals to controller 330. In some embodiments, AHU controller 330 receives a measurement of the supply air temperature from a temperature sensor 362 positioned in supply air duct 312 (e.g., downstream of cooling coil 334 and/or heating coil 336). AHU controller 330 may also receive a measurement of the temperature of building zone 306 from a temperature sensor 364 located in building zone 306.

In some embodiments, AHU controller 330 operates valves 346 and 352 via actuators 354-356 to modulate an amount of heating or cooling provided to supply air 310 (e.g., to achieve a setpoint temperature for supply air 310 or to maintain the temperature of supply air 310 within a setpoint temperature range). The positions of valves 346 and 352 affect the amount of heating or cooling provided to supply air 310 by cooling coil 334 or heating coil 336 and may correlate with the amount of energy consumed to achieve a desired supply air temperature. AHU 330 may control the temperature of supply air 310 and/or building zone 306 by activating or deactivating coils 334-336, adjusting a speed of fan 338, or a combination of both.

Still referring to FIG. 3, airside system 300 is shown to include a building management system (BMS) controller 366 and a client device 368. BMS controller 366 can include one or more computer systems (e.g., servers, supervisory controllers, subsystem controllers, etc.) that serve as system level controllers, application or data servers, head nodes, or master controllers for airside system 300, waterside system 200, HVAC system 100, and/or other controllable systems that serve building 10. BMS controller 366 may communicate with multiple downstream building systems or subsystems (e.g., HVAC system 100, a security system, a lighting system, waterside system 200, etc.) via a communications link 370 according to like or disparate protocols (e.g., LON, BACnet, etc.). In various embodiments, AHU controller 330 and BMS controller 366 can be separate (as shown in FIG. 3) or integrated. In an integrated implementation, AHU controller 330 can be a software module configured for execution by a processor of BMS controller 366.

In some embodiments, AHU controller 330 receives information from BMS controller 366 (e.g., commands, setpoints, operating boundaries, etc.) and provides information to BMS controller 366 (e.g., temperature measurements, valve or actuator positions, operating statuses, diagnostics, etc.). For example, AHU controller 330 may provide BMS controller 366 with temperature measurements from temperature sensors 362-364, equipment on/off states, equipment operating capacities, and/or any other information that can be used by BMS controller 366 to monitor or control a variable state or condition within building zone 306.

Client device 368 can include one or more human-machine interfaces or client interfaces (e.g., graphical user interfaces, reporting interfaces, text-based computer interfaces, client-facing web services, web servers that provide pages to web clients, etc.) for controlling, viewing, or otherwise interacting with HVAC system 100, its subsystems, and/or devices. Client device 368 can be a computer workstation, a client terminal, a remote or local interface, or any other type of user interface device. Client device 368 can be a stationary terminal or a mobile device. For example, client device 368 can be a desktop computer, a computer server with a user interface, a laptop computer, a tablet, a smartphone, a PDA, or any other type of mobile or non-mobile device. Client device 368 may communicate with BMS controller 366 and/or AHU controller 330 via communications link 372.

### Building Management Systems

Referring now to FIG. 4, a block diagram of a building management system (BMS) 400 is shown, according to some embodiments. BMS 400 can be implemented in building 10 to automatically monitor and control various building functions. BMS 400 is shown to include BMS controller 366 and a plurality of building subsystems 428. Building subsystems 428 are shown to include a building electrical subsystem 434, an information communication technology (ICT) subsystem 436, a security subsystem 438, a HVAC subsystem 440, a lighting subsystem 442, a lift/escalators subsystem 432, and a fire safety subsystem 430. In various embodiments, building subsystems 428 can include fewer, additional, or alternative subsystems. For example, building subsystems 428 may also or alternatively include a refrigeration subsystem, an advertising or signage subsystem, a cooking subsystem, a vending subsystem, a printer or copy service subsystem, or any other type of building subsystem that uses controllable equipment and/or sensors to monitor or control building 10. In some embodiments, building subsystems 428 include waterside system 200 and/or airside system 300, as described with reference to FIGS. 2-3.

Each of building subsystems 428 can include any number of devices, controllers, and connections for completing its individual functions and control activities. HVAC subsystem 440 can include many of the same components as HVAC system 100, as described with reference to FIGS. 1-3. For example, HVAC subsystem 440 can include a chiller, a boiler, any number of air handling units, economizers, field controllers, supervisory controllers, actuators, temperature sensors, and other devices for controlling the temperature, humidity, airflow, or other variable conditions within building 10. Lighting subsystem 442 can include any number of light fixtures, ballasts, lighting sensors, dimmers, or other devices configured to controllably adjust the amount of light provided to a building space. Security subsystem 438 can include occupancy sensors, video surveillance cameras, digital video recorders, video processing servers, intrusion detection devices, access control devices and servers, or other security-related devices.

Still referring to FIG. 4, BMS controller 366 is shown to include a communications interface 407 and a BMS interface 409. Interface 407 may facilitate communications between BMS controller 366 and external applications (e.g., monitoring and reporting applications 422, enterprise control applications 426, remote systems and applications 444, applications residing on client devices 448, etc.) for allowing user control, monitoring, and adjustment to BMS controller 366 and/or subsystems 428. Interface 407 may also facilitate communications between BMS controller 366 and client devices 448. BMS interface 409 may facilitate communications between BMS controller 366 and building subsystems 428 (e.g., HVAC, lighting security, lifts, power distribution, business, etc.).

Interfaces 407, 409 can be or include wired or wireless communications interfaces (e.g., jacks, antennas, transmitters, receivers, transceivers, wire terminals, etc.) for conducting data communications with building subsystems 428 or other external systems or devices. In various embodiments, communications via interfaces 407, 409 can be direct (e.g., local wired or wireless communications) or via a communications network 446 (e.g., a WAN, the Internet, a cellular network, etc.). For example, interfaces 407, 409 can include an Ethernet card and port for sending and receiving data via an Ethernet-based communications link or network. In another example, interfaces 407, 409 can include a Wi-Fi transceiver for communicating via a wireless communications network. In another example, one or both of interfaces 407, 409 can include cellular or mobile phone communications transceivers. In one embodiment, communications interface 407 is a power line communications interface and BMS interface 409 is an Ethernet interface. In other embodiments, both communications interface 407 and BMS interface 409 are Ethernet interfaces or are the same Ethernet interface.

Still referring to FIG. 4, BMS controller 366 is shown to include a processing circuit 404 including a processor 406 and memory 408. Processing circuit 404 can be communicably connected to BMS interface 409 and/or communications interface 407 such that processing circuit 404 and the various components thereof can send and receive data via interfaces 407, 409. Processor 406 can be implemented as a general purpose processor, an application specific integrated circuit (ASIC), one or more field programmable gate arrays (FPGAs), a group of processing components, or other suitable electronic processing components.

Memory 408 (e.g., memory, memory unit, storage device, etc.) can include one or more devices (e.g., RAM, ROM, Flash memory, hard disk storage, etc.) for storing data and/or computer code for completing or facilitating the various processes, layers and modules described in the present application. Memory 408 can be or include volatile memory or non-volatile memory. Memory 408 can include database components, object code components, script components, or any other type of information structure for supporting the various activities and information structures described in the present application. According to some embodiments, memory 408 is communicably connected to processor 406 via processing circuit 404 and includes computer code for executing (e.g., by processing circuit 404 and/or processor 406) one or more processes described herein.

In some embodiments, BMS controller 366 is implemented within a single computer (e.g., one server, one housing, etc.). In various other embodiments BMS controller 366 can be distributed across multiple servers or computers (e.g., that can exist in distributed locations). Further, while FIG. 4 shows applications 422 and 426 as existing outside of BMS controller 366, in some embodiments, applications 422 and 426 can be hosted within BMS controller 366 (e.g., within memory 408).

Still referring to FIG. 4, memory 408 is shown to include an enterprise integration layer 410, an automated measurement and validation (AM&V) layer 412, a demand response (DR) layer 414, a fault detection and diagnostics (FDD) layer 416, an integrated control layer 418, and a building subsystem integration later 420. Layers 410-420 can be configured to receive inputs from building subsystems 428 and other data sources, determine optimal control actions for building subsystems 428 based on the inputs, generate control signals based on the optimal control actions, and provide the generated control signals to building subsystems 428. The following paragraphs describe some of the general functions performed by each of layers 410-420 in BMS 400.

Enterprise integration layer 410 can be configured to serve clients or local applications with information and services to support a variety of enterprise-level applications. For example, enterprise control applications 426 can be configured to provide subsystem-spanning control to a graphical user interface (GUI) or to any number of enterprise-level business applications (e.g., accounting systems, user identification systems, etc.). Enterprise control applications 426 may also or alternatively be configured to provide configuration GUIs for configuring BMS controller 366. In yet other embodiments, enterprise control applications 426 can work with layers 410-420 to optimize building performance (e.g., efficiency, energy use, comfort, or safety) based on inputs received at interface 407 and/or BMS interface 409.

Building subsystem integration layer 420 can be configured to manage communications between BMS controller 366 and building subsystems 428. For example, building subsystem integration layer 420 may receive sensor data and input signals from building subsystems 428 and provide output data and control signals to building subsystems 428. Building subsystem integration layer 420 may also be configured to manage communications between building subsystems 428. Building subsystem integration layer 420 translate communications (e.g., sensor data, input signals, output signals, etc.) across a plurality of multi-vendor/multi-protocol systems.

Demand response layer 414 can be configured to optimize resource usage (e.g., electricity use, natural gas use, water use, etc.) and/or the monetary cost of such resource usage in response to satisfy the demand of building 10. The optimization can be based on time-of-use prices, curtailment signals, energy availability, or other data received from utility providers, distributed energy generation systems 424, from energy storage 427 (e.g., hot TES 242, cold TES 244, etc.), or from other sources. Demand response layer 414 may receive inputs from other layers of BMS controller 366 (e.g., building subsystem integration layer 420, integrated control layer 418, etc.). The inputs received from other layers can include environmental or sensor inputs such as temperature, carbon dioxide levels, relative humidity levels, air quality sensor outputs, occupancy sensor outputs, room schedules, and the like. The inputs may also include inputs such as electrical use (e.g., expressed in kWh), thermal load measurements, pricing information, projected pricing, smoothed pricing, curtailment signals from utilities, and the like.

According to some embodiments, demand response layer 414 includes control logic for responding to the data and signals it receives. These responses can include communicating with the control algorithms in integrated control layer 418, changing control strategies, changing setpoints, or activating/deactivating building equipment or subsystems in a controlled manner. Demand response layer 414 may also include control logic configured to determine when to utilize stored energy. For example, demand response layer 414 may determine to begin using energy from energy storage 427 just prior to the beginning of a peak use hour.

In some embodiments, demand response layer 414 includes a control module configured to actively initiate control actions (e.g., automatically changing setpoints) which minimize energy costs based on one or more inputs representative of or based on demand (e.g., price, a curtailment signal, a demand level, etc.). In some embodiments, demand response layer 414 uses equipment models to determine an optimal set of control actions. The equipment models can include, for example, thermodynamic models describing the inputs, outputs, and/or functions performed by various sets of building equipment. Equipment models may represent collections of building equipment (e.g., subplants, chiller arrays, etc.) or individual devices (e.g., individual chillers, heaters, pumps, etc.).

Demand response layer 414 may further include or draw upon one or more demand response policy definitions (e.g., databases, XML files, etc.). The policy definitions can be edited or adjusted by a user (e.g., via a graphical user interface) so that the control actions initiated in response to demand inputs can be tailored for the user's application, desired comfort level, particular building equipment, or based on other concerns. For example, the demand response policy definitions can specify which equipment can be turned on or off in response to particular demand inputs, how long a system or piece of equipment should be turned off, what setpoints can be changed, what the allowable set point adjustment range is, how long to hold a high demand setpoint before returning to a normally scheduled setpoint, how close to approach capacity limits, which equipment modes to utilize, the energy transfer rates (e.g., the maximum rate, an alarm rate, other rate boundary information, etc.) into and out of energy storage devices (e.g., thermal storage tanks, battery banks, etc.), and when to dispatch on-site generation of energy (e.g., via fuel cells, a motor generator set, etc.).

Integrated control layer 418 can be configured to use the data input or output of building subsystem integration layer 420 and/or demand response later 414 to make control decisions. Due to the subsystem integration provided by building subsystem integration layer 420, integrated control layer 418 can integrate control activities of the subsystems 428 such that the subsystems 428 behave as a single integrated supersystem. In some embodiments, integrated control layer 418 includes control logic that uses inputs and outputs from a plurality of building subsystems to provide greater comfort and energy savings relative to the comfort and energy savings that separate subsystems could provide alone. For example, integrated control layer 418 can be configured to use an input from a first subsystem to make an energy-saving control decision for a second subsystem. Results of these decisions can be communicated back to building subsystem integration layer 420.

Integrated control layer 418 is shown to be logically below demand response layer 414. Integrated control layer 418 can be configured to enhance the effectiveness of demand response layer 414 by enabling building subsystems 428 and their respective control loops to be controlled in coordination with demand response layer 414. This configuration may advantageously reduce disruptive demand response behavior relative to conventional systems. For example, integrated control layer 418 can be configured to assure that a demand response-driven upward adjustment to the setpoint for chilled water temperature (or another component that directly or indirectly affects temperature) does not result in an increase in fan energy (or other energy used to cool a space) that would result in greater total building energy use than was saved at the chiller.

Integrated control layer 418 can be configured to provide feedback to demand response layer 414 so that demand response layer 414 checks that constraints (e.g., temperature, lighting levels, etc.) are properly maintained even while demanded load shedding is in progress. The constraints may also include setpoint or sensed boundaries relating to safety, equipment operating limits and performance, comfort, fire codes, electrical codes, energy codes, and the like. Integrated control layer 418 is also logically below fault detection and diagnostics layer 416 and automated measurement and validation layer 412. Integrated control layer 418 can be configured to provide calculated inputs (e.g., aggregations) to these higher levels based on outputs from more than one building subsystem.

Automated measurement and validation (AM&V) layer 412 can be configured to verify that control strategies commanded by integrated control layer 418 or demand response layer 414 are working properly (e.g., using data aggregated by AM&V layer 412, integrated control layer 418, building subsystem integration layer 420, FDD layer 416, or otherwise). The calculations made by AM&V layer 412 can be based on building system energy models and/or equipment models for individual BMS devices or subsystems. For example, AM&V layer 412 may compare a model-predicted output with an actual output from building subsystems 428 to determine an accuracy of the model.

Fault detection and diagnostics (FDD) layer 416 can be configured to provide on-going fault detection for building subsystems 428, building subsystem devices (i.e., building equipment), and control algorithms used by demand response layer 414 and integrated control layer 418. FDD layer 416 may receive data inputs from integrated control layer 418, directly from one or more building subsystems or devices, or from another data source. FDD layer 416 may automatically diagnose and respond to detected faults. The responses to detected or diagnosed faults can include providing an alert message to a user, a maintenance scheduling system, or a control algorithm configured to attempt to repair the fault or to work-around the fault.

FDD layer 416 can be configured to output a specific identification of the faulty component or cause of the fault (e.g., loose damper linkage) using detailed subsystem inputs available at building subsystem integration layer 420. In other exemplary embodiments, FDD layer 416 is configured to provide “fault” events to integrated control layer 418 which executes control strategies and policies in response to the received fault events. According to some embodiments, FDD layer 416 (or a policy executed by an integrated control engine or business rules engine) may shut-down systems or direct control activities around faulty devices or systems to reduce energy waste, extend equipment life, or assure proper control response.

FDD layer 416 can be configured to store or access a variety of different system data stores (or data points for live data). FDD layer 416 may use some content of the data stores to identify faults at the equipment level (e.g., specific chiller, specific AHU, specific terminal unit, etc.) and other content to identify faults at component or subsystem levels. For example, building subsystems 428 may generate temporal (i.e., time-series) data indicating the performance of BMS 400 and the various components thereof. The data generated by building subsystems 428 can include measured or calculated values that exhibit statistical characteristics and provide information about how the corresponding system or process (e.g., a temperature control process, a flow control process, etc.) is performing in terms of error from its setpoint. These processes can be examined by FDD layer 416 to expose when the system begins to degrade in performance and alert a user to repair the fault before it becomes more severe.

Referring now to FIG. 5, a block diagram of another building management system (BMS) 500 is shown, according to some embodiments. BMS 500 can be used to monitor and control the devices of HVAC system 100, waterside system 200, airside system 300, building subsystems 428, as well as other types of BMS devices (e.g., lighting equipment, security equipment, etc.) and/or HVAC equipment.

BMS 500 provides a system architecture that facilitates automatic equipment discovery and equipment model distribution. Equipment discovery can occur on multiple levels of BMS 500 across multiple different communications busses (e.g., a system bus 554, zone buses 556-560 and 564, sensor/actuator bus 566, etc.) and across multiple different communications protocols. In some embodiments, equipment discovery is accomplished using active node tables, which provide status information for devices connected to each communications bus. For example, each communications bus can be monitored for new devices by monitoring the corresponding active node table for new nodes. When a new device is detected, BMS 500 can begin interacting with the new device (e.g., sending control signals, using data from the device) without user interaction.

Some devices in BMS 500 present themselves to the network using equipment models. An equipment model defines equipment object attributes, view definitions, schedules, trends, and the associated BACnet value objects (e.g., analog value, binary value, multistate value, etc.) that are used for integration with other systems. Some devices in BMS 500 store their own equipment models. Other devices in BMS 500 have equipment models stored externally (e.g., within other devices). For example, a zone coordinator 508 can store the equipment model for a bypass damper 528. In some embodiments, zone coordinator 508 automatically creates the equipment model for bypass damper 528 or other devices on zone bus 558. Other zone coordinators can also create equipment models for devices connected to their zone busses. The equipment model for a device can be created automatically based on the types of data points exposed by the device on the zone bus, device type, and/or other device attributes. Several examples of automatic equipment discovery and equipment model distribution are discussed in greater detail below.

Still referring to FIG. 5, BMS 500 is shown to include a system manager 502; several zone coordinators 506, 508, 510 and 518; and several zone controllers 524, 530, 532, 536, 548, and 550. System manager 502 can monitor data points in BMS 500 and report monitored variables to various monitoring and/or control applications. System manager 502 can communicate with client devices 504 (e.g., user devices, desktop computers, laptop computers, mobile devices, etc.) via a data communications link 574 (e.g., BACnet IP, Ethernet, wired or wireless communications, etc.). System manager 502 can provide a user interface to client devices 504 via data communications link 574. The user interface may allow users to monitor and/or control BMS 500 via client devices 504.

In some embodiments, system manager 502 is connected with zone coordinators 506-510 and 518 via a system bus 554. System manager 502 can be configured to communicate with zone coordinators 506-510 and 518 via system bus 554 using a master-slave token passing (MSTP) protocol or any other communications protocol. System bus 554 can also connect system manager 502 with other devices such as a constant volume (CV) rooftop unit (RTU) 512, an input/output module (IOM) 514, a thermostat controller 516 (e.g., a TEC5000 series thermostat controller), and a network automation engine (NAE) or third-party controller 520. RTU 512 can be configured to communicate directly with system manager 502 and can be connected directly to system bus 554. Other RTUs can communicate with system manager 502 via an intermediate device. For example, a wired input 562 can connect a third-party RTU 542 to thermostat controller 516, which connects to system bus 554.

System manager 502 can provide a user interface for any device containing an equipment model. Devices such as zone coordinators 506-510 and 518 and thermostat controller 516 can provide their equipment models to system manager 502 via system bus 554. In some embodiments, system manager 502 automatically creates equipment models for connected devices that do not contain an equipment model (e.g., IOM 514, third party controller 520, etc.). For example, system manager 502 can create an equipment model for any device that responds to a device tree request. The equipment models created by system manager 502 can be stored within system manager 502. System manager 502 can then provide a user interface for devices that do not contain their own equipment models using the equipment models created by system manager 502. In some embodiments, system manager 502 stores a view definition for each type of equipment connected via system bus 554 and uses the stored view definition to generate a user interface for the equipment.

Each zone coordinator 506-510 and 518 can be connected with one or more of zone controllers 524, 530-532, 536, and 548-550 via zone buses 556, 558, 560, and 564. Zone coordinators 506-510 and 518 can communicate with zone controllers 524, 530-532, 536, and 548-550 via zone busses 556-560 and 564 using a MSTP protocol or any other communications protocol. Zone busses 556-560 and 564 can also connect zone coordinators 506-510 and 518 with other types of devices such as variable air volume (VAV) RTUs 522 and 540, changeover bypass (COBP) RTUs 526 and 552, bypass dampers 528 and 546, and PEAK controllers 534 and 544.

Zone coordinators 506-510 and 518 can be configured to monitor and command various zoning systems. In some embodiments, each zone coordinator 506-510 and 518 monitors and commands a separate zoning system and is connected to the zoning system via a separate zone bus. For example, zone coordinator 506 can be connected to VAV RTU 522 and zone controller 524 via zone bus 556. Zone coordinator 508 can be connected to COBP RTU 526, bypass damper 528, COBP zone controller 530, and VAV zone controller 532 via zone bus 558. Zone coordinator 510 can be connected to PEAK controller 534 and VAV zone controller 536 via zone bus 560. Zone coordinator 518 can be connected to PEAK controller 544, bypass damper 546, COBP zone controller 548, and VAV zone controller 550 via zone bus 564.

A single model of zone coordinator 506-510 and 518 can be configured to handle multiple different types of zoning systems (e.g., a VAV zoning system, a COBP zoning system, etc.). Each zoning system can include a RTU, one or more zone controllers, and/or a bypass damper. For example, zone coordinators 506 and 510 are shown as Verasys VAV engines (VVEs) connected to VAV RTUs 522 and 540, respectively. Zone coordinator 506 is connected directly to VAV RTU 522 via zone bus 556, whereas zone coordinator 510 is connected to a third-party VAV RTU 540 via a wired input 568 provided to PEAK controller 534. Zone coordinators 508 and 518 are shown as Verasys COBP engines (VCEs) connected to COBP RTUs 526 and 552, respectively. Zone coordinator 508 is connected directly to COBP RTU 526 via zone bus 558, whereas zone coordinator 518 is connected to a third-party COBP RTU 552 via a wired input 570 provided to PEAK controller 544.

Zone controllers 524, 530-532, 536, and 548-550 can communicate with individual BMS devices (e.g., sensors, actuators, etc.) via sensor/actuator (SA) busses. For example, VAV zone controller 536 is shown connected to networked sensors 538 via SA bus 566. Zone controller 536 can communicate with networked sensors 538 using a MSTP protocol or any other communications protocol. Although only one SA bus 566 is shown in FIG. 5, it should be understood that each zone controller 524, 530-532, 536, and 548-550 can be connected to a different SA bus. Each SA bus can connect a zone controller with various sensors (e.g., temperature sensors, humidity sensors, pressure sensors, light sensors, occupancy sensors, etc.), actuators (e.g., damper actuators, valve actuators, etc.) and/or other types of controllable equipment (e.g., chillers, heaters, fans, pumps, etc.).

Each zone controller 524, 530-532, 536, and 548-550 can be configured to monitor and control a different building zone. Zone controllers 524, 530-532, 536, and 548-550 can use the inputs and outputs provided via their SA busses to monitor and control various building zones. For example, a zone controller 536 can use a temperature input received from networked sensors 538 via SA bus 566 (e.g., a measured temperature of a building zone) as feedback in a temperature control algorithm. Zone controllers 524, 530-532, 536, and 548-550 can use various types of control algorithms (e.g., state-based algorithms, extremum seeking control (ESC) algorithms, proportional-integral (PI) control algorithms, proportional-integral-derivative (PID) control algorithms, model predictive control (MPC) algorithms, feedback control algorithms, etc.) to control a variable state or condition (e.g., temperature, humidity, airflow, lighting, etc.) in or around building 10.

### Building Equipment Construction Tool With Generative AI-Based Synthesis

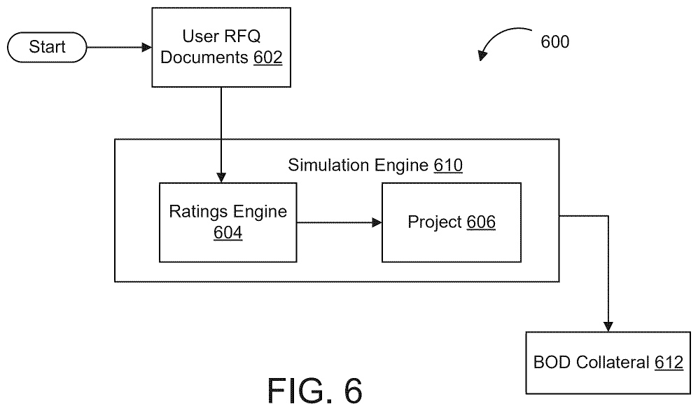

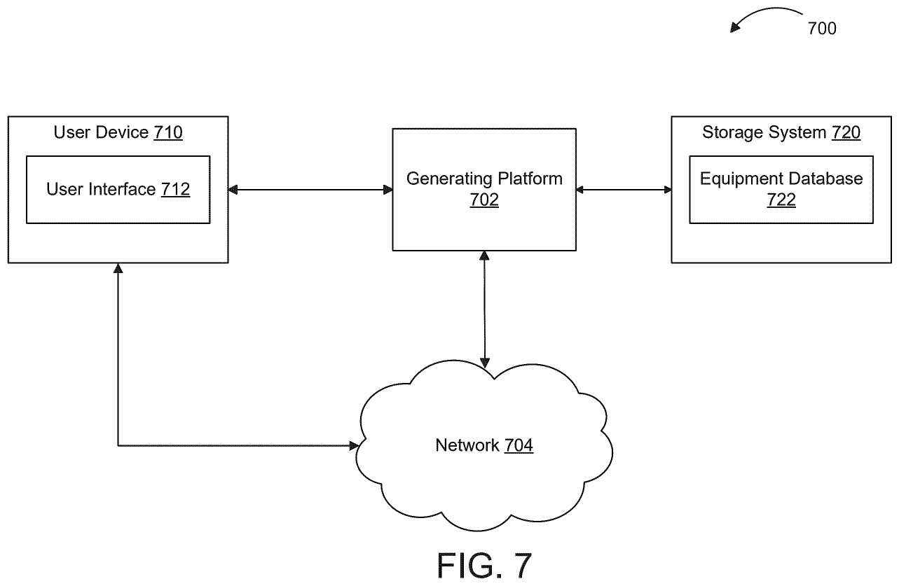

Referring now to FIG. 6, a block diagram of a system 600 is shown, according to an exemplary embodiment. System 600 is shown to include a simulation engine 610 which can be used to generate a basis of design (BOD) collateral 612 based on a request for quotation (RFQ) provided as an input. In previous systems such as system 600, the simulation engine 610 can be used to generate a new set of BOD collateral 612 for every user request. The systems and methods described herein improve upon the technique illustrated in FIG. 6 as described in greater detail with reference to FIGS. 7-10.

Simulation engine 610 may receive user RFQ documents 602 as an input and generate a BOD collateral 612 based on the user RFQ documents 602, according to some embodiments. The simulation engine 610 includes a ratings engine 604 and a project 606. The ratings engine 604 runs a physics-based or rules-based simulation to predict real values from real scenarios. The input from the user RFQ documents 602 describes the entire simulation environment and requirements for the simulation including room size, energy consumption requirements, temperature requirements, etc. in some embodiments. The ratings engine 604 then generates possible outcomes based on the inputs and creates a project 606 for each situation. The project 606 stores all the parameters and outputs together. The simulation engine 610 then selects equipment items based on said parameters and outputs. The selection of equipment items is the final step of the simulation engine 610 which makes the selection of the generated equipment items for a final set of equipment items. In some embodiments, the final set of equipment items is utilized to generate a BOD collateral 612 that is the final output.

In some embodiments, the simulation engine 610 makes a selection of equipment items based on factors including the energy consumption, cost, installation means, material, static pressure, etc. of said equipment items. In some embodiments, the equipment items include a chiller that removes heat and introduces cold through chilled water circulation. In some embodiments, the equipment items include a VAV box regulating airflow in a building. In some embodiments, the equipment items include air handlers regulating and circulating air in a building. In some embodiments, the equipment items are simulated by the simulation engine 610 with specification received from the user through RFQ documents 602 including information on airflow, static pressure, cost, etc. features.

Referring now to FIG. 7, a block diagram of a system 700 is shown, according to an exemplary embodiment. System 700 is shown to include several components that cooperate with each other to perform the functions of a building equipment construction tool. For example, system 700 is shown to include a generating platform 702, a network 704, a user device 710, and a storage system 720. The generating platform 702 interacts with the storage system 720 to retrieve data from the building equipment device database 722. The user device 710 may include a user interface 712 to display and collect information from the user. The user device 710 interacts with the network 704 to send the user RFQ documents to the generating platform 702. In some embodiments, the generating platform 702 also retrieves information from the storage system 720 to retrieve additional information used with an AI model and simulation engine.

The generating platform 702 is the main component for generating the BOD collateral. In some embodiments, the generating platform 702 receives user documents from the user device 710 in the form of building requirements, equipment specifications, etc. that give the generating platform 702 a basis for generating a BOD collateral. A trained AI model is in the generating platform 702 along with a simulation engine to generate a BOD collateral from the configuration or simulate a new BOD collateral when there is not a suitable generation. In some embodiments, the generating platform 702 interacts with the network 704 to collect and interpret information from a user device 710 used for the generation of a BOD collateral.

The network 704 is a component for connecting localized items like the generating platform 702 with the user device 710. The network 704 is a WAN, the internet, a cellular network, etc. that handles communication over the user device 710 and the generating platform 702. The network 704 may control how the information provided by the user is sent to the generating platform 702. In some embodiments, the network 704 receives information from the user including building requirements, equipment specifications, etc. and sends said information to the generating platform 702.

The user device 710 may include a user interface 712 that displays to the user how to send information to the generating platform 702. The user device 710 controls what information is requested from the user and how the user may send information through the network 704 to the generating platform 702. In some embodiments, the user interface 712 may communicate with an AI interpreter that communicates with the user building requirements, equipment specifications, etc. and sends information to the generating platform 702 generating a BOD collateral to be sent to the user. In some embodiments, the user interface 712 includes a file selector to incorporate files containing building requirements, equipment specifications, etc. to be interpreted and sent across a network 704 to be utilized in the generating platform 702 to generate a BOD collateral.

The storage system 720 is a component that may include a building equipment device database 722. The storage system 720 communicates with the generating platform 702 to provide supplemental information for generation that may not be included in the information from the user device 710. The supplemental information includes additional general building requirements, equipment information and limitations, etc. and is utilized to optimize generation of the BOD collateral. The building equipment device database 722 may include building equipment devices with information regarding size, energy consumption, installation means, etc. to aid the generating platform 702 in selecting the best options for the user. In some embodiments, the storage system 720 aids the user device 710 with information sent to the generating platform 702 to generate an optimal BOD collateral.

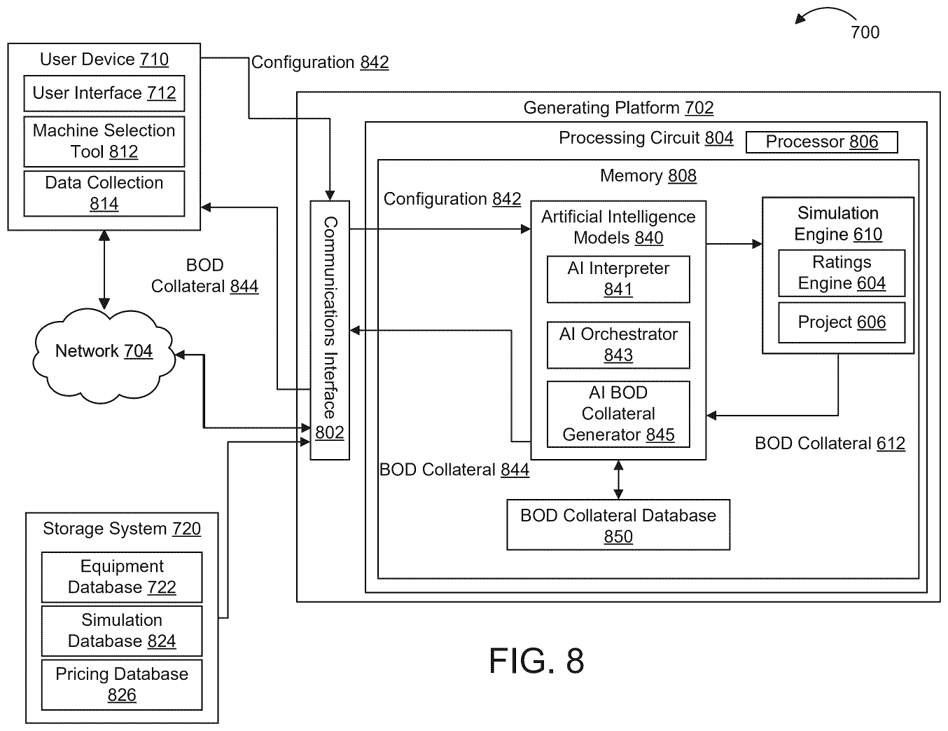

Referring now to FIG. 8, a block diagram illustrating the generating platform 702 and other components of system 700 in greater detail is shown, according to an exemplary embodiment. System 700 may be a building equipment construction system. The generating platform 702 can be configured for training an AI BOD collateral generator 845 using simulated data generated by the simulation engine 610. The AI BOD collateral generator 845 communicates with a communication interface 802 and the simulation engine 610 to train on data and provide results to a user. The communication interface 802 controls the communication between the user device 710, the network 704, and the storage system 720. A processing circuit 804 of the generating platform 702 includes several functional components that cooperate to train the AI BOD collateral generator 845 and generate simulated data using the simulation engine 610. The proprietary data included in the BOD collateral database 850 gives the AI BOD collateral generator 845 unique training data to optimize results.

The processing circuit 804 is shown to include a processor 806 and memory 808. A processing circuit 804 including a processor 806 and memory 808. Processing circuit 804 can be communicably connected to the communications interface 802 such that processing circuit 804 and the various components thereof can send and receive data via the communications interface 802. Processor 806 can be implemented as a general purpose processor, an application specific integrated circuit (ASIC), one or more field programmable gate arrays (FPGAs), a group of processing components, or other suitable electronic processing components.

Memory 808 (e.g., memory, memory unit, storage device, etc.) can include one or more devices (e.g., RAM, ROM, Flash memory, hard disk storage, etc.) for storing data and/or computer code for completing or facilitating the various processes, layers and modules described in the present application. Memory 808 can be or include volatile memory or non-volatile memory. Memory 808 can include database components, object code components, script components, or any other type of information structure for supporting the various activities and information structures described in the present application. According to some embodiments, memory 808 is communicably connected to processor 806 via processing circuit 804 and includes computer code for executing (e.g., by processing circuit 804 and/or processor 806) one or more processes described herein.

The processor 806 provides the environment to train the AI BOD collateral generator 845 with the BOD collateral database 850 data and the simulation engine 610 data. The simulation engine 610 includes a ratings engine 604, a project 606. The ratings engine 604 runs a physics-based or rules-based simulation to predict how equipment would perform in operation, power consumption, cooling tonnage, along with other considerations. The project 606 defines the conditions for the simulation including specific specifications for the equipment. In some embodiments, the output of the simulation engine 610 is a BOD collateral 612 including system diagrams, drawings, data sheets and device ratings.

The ratings engine 604 runs a physics-based or rules-based simulation to predict how equipment would perform in operation, power consumption, cooling tonnage, along with other considerations. In some embodiments, the simulation is performed by setting parameters that define the building, system, and equipment configurations to calculate different values like temperature, etc. The calculations from the ratings engine 604 may represent the values expected if the exact simulation were performed with the proper equipment in the proper building. In some embodiments, the ratings engine 604 removes the need to build the entire setup for a demonstration and instead allows for a large number of simulated setups to provide predicted values and demonstrate the best options.

The project 606 may store the conditions for which the simulation took place and the results which took place. In some embodiments, the project 606 allows for an increased speed and accuracy of simulation with existing projects that contain the same specifications. In some embodiments, the project 606 is the intermediate step between selecting the best equipment items for the BOD collateral 612 from the simulation and the ratings engine 604 calculating results.

In some embodiments, the first BOD collateral 612 is generated from the simulation engine 610 configured to provide training input to an AI BOD collateral generator 845. The first BOD collateral 612 may include first simulated building equipment performance ratings based on first user requests including first building equipment operating requirements. The first BOD collateral 612 may include a bill of materials (BOM) data, drawings, unit specifications, performance ratings, warranties, data sheets, etc. The AI BOD collateral generator 845 may use the configuration 842 including the first user requests and the first BOD collateral 612 as training data to train the AI BOD collateral generator 845. The first BOD collateral 612 may be the result of the simulation engine 610. In another embodiment, the first BOD collateral 612 is used as the second BOD collateral 844 returned to the user device 710.

The generating platform 702 is shown to include a communications interface 802. The communications interface 802 may facilitate communications between the network 704, the user device 710, and the AI models 840 to allow users to send RFQ documents. The communications interface 802 may also facilitate communication between the AI models 840 and the storage system 720 to collect supplemental information to assist the AI models 840 in optimizing results. In some embodiments, communications via the communications interface 802 can be the transfer of data, or the transmission of results.

In some embodiments, the machine selection tool 812 works with the data collection 814 to take documents from the user interface 712 to interpret data and select the machines to be designed. The machine selection tool 812 may select the machine to be designed by interpreting documents, conversating with the user, etc. The machine selected may be the main design point for the BOD collateral 844. The data collection 814 may be the process of collecting data from a user device 710 to interpret the data provided and complete processes based on the data. In some embodiments, the data includes RFQ documents that contain information regarding the machine needs.

In some embodiments, the storage system 720 includes an equipment database 722, a simulation database 824, and a pricing database 826. The equipment database 722 may include information regarding equipment items such as size, cooling tonnage, energy consumption, etc. to be utilized by the AI models 840 and the simulation engine 610. The equipment database 722 may provide the equipment information to the AI models 840 through the communication interface 802. In some embodiments, the equipment database 722 includes equipment items generated by the simulation engine 610. In some embodiments, the equipment database 722 includes equipment items generated by the AI BOD collateral generator 845. For example, the AI BOD collateral generator 845 may generate a chiller to be sent to the user device 710 through a BOD collateral 844, and the chiller equipment may be stored in the equipment database 722. The simulation database 824 may include information regarding information from the simulation engine 610. In some embodiments, the simulation database 824 includes information from a project 606 simulated within a simulation engine 610. The simulation database 824 may store information including the simulated building dimensions, the desired specifications of the equipment, the outcomes of a simulation, etc. The pricing database 826 may include information regarding the price of equipment or materials. The pricing of equipment may be under consideration for the user and the pricing database 826 may supply supplemental information to the AI models 840 for training.

The AI models 840 can include one or more neural networks, including neural networks configured as generative models. For example, the AI models 840 can predict or generate new data (e.g., artificial data; synthetic data; data not explicitly represented in data used for configuring the AI models 840). The AI models 840 can generate any of a variety of modalities of materials, such as text and images. The neural network can include a plurality of nodes, which may be arranged in layers for providing outputs of one or more nodes of one layer as inputs to one or more nodes of another layer. The neural network can include one or more input layers, one or more hidden layers, and one or more output layers. Each node can include or be associated with parameters such as weights, biases, and/or thresholds, representing how the node can perform computations to process inputs to generate outputs. The parameters of the nodes can be configured by various learning or training operations, such as unsupervised learning, weakly supervised learning, semi-supervised learning, or supervised learning.

The AI models 840 can include, for example and without limitation, one or more language models, LLMs, attention-based neural networks, transformer-based neural networks, generative pretrained transformer (GPT) models, bidirectional encoder representations from transformers (BERT) models, encoder/decoder models, sequence to sequence models, autoencoder models, generative adversarial networks (GANs), convolutional neural networks (CNNs), recurrent neural networks (RNNs), diffusion models (e.g., denoising diffusion probabilistic models (DDPMs)), or various combinations thereof.

For example, the AI models 840 can include at least one GPT model. The GPT model can receive an input sequence, and can parse the input sequence to determine a sequence of tokens (e.g., words or other semantic units of the input sequence, such as by using Byte Pair Encoding tokenization). The GPT model can include or be coupled with a vocabulary of tokens, which can be represented as a one-hot encoding vector, where each token of the vocabulary has a corresponding index in the encoding vector; as such, the GPT model can convert the input sequence into a modified input sequence, such as by applying an embedding matrix to the token tokens of the input sequence (e.g., using a neural network embedding function), and/or applying positional encoding (e.g., sin-cosine positional encoding) to the tokens of the input sequence. The GPT model can process the modified input sequence to determine a next token in the sequence (e.g., to append to the end of the sequence), such as by determining probability scores indicating the likelihood of one or more candidate tokens being the next token, and selecting the next token according to the probability scores (e.g., selecting the candidate token having the highest probability scores as the next token). For example, the GPT model can apply various attention and/or transformer based operations or networks to the modified input sequence to identify relationships between tokens for detecting the next token to form the output sequence.

The AI models 840 can include at least one diffusion model, which can be used to generate image data. For example, the diffusional model can include a denoising neural network and/or a denoising diffusion probabilistic model neural network. The denoising neural network can be configured by applying noise to one or more training data elements (e.g., images) to generate noised data, providing the noised data as input to a candidate denoising neural network, causing the candidate denoising neural network to modify the noised data according to a denoising schedule, evaluating a convergence condition based on comparing the modified noised data with the training data instances, and modifying the candidate denoising neural network according to the convergence condition (e.g., modifying weights and/or biases of one or more layers of the neural network). In some implementations, the AI models 840 includes a plurality of generative models, such as GPT and diffusion models, that can be trained separately or jointly to facilitate generating multi-modal outputs, such as technical documents (e.g., service guides) that include both text and image information.

In some implementations, the AI models 840 can be configured using various unsupervised and/or supervised training operations. The AI models 840 can be configured using training data from various domain-agnostic and/or domain-specific data sources, including but not limited to various forms of text and/or image data. The training data can include a plurality of training data elements (e.g., training data instances). Each training data element can be arranged in structured or unstructured formats; for example, the training data element can include an example output mapped to an example input, such as a query representing a RFQ or one or more portions of a RFQ, and a response representing data provided responsive to the query. The training data can include data that is not separated into input and output subsets (e.g., for configuring the AI models 840 to perform clustering, classification, or other unsupervised ML operations). The training data can include human-labeled information, including but not limited to feedback regarding outputs of the AI models 840 or the simulation engine 610.

In some embodiments, the AI models 840 may include an AI interpreter 841, an AI orchestrator 843, and an AI BOD collateral generator 845. In some embodiments, the AI interpreter 841 may communicate with the user device 710 to determine the configuration 842. The AI interpreter 841 may process a request and may determine one or more of information is missing, all information is provided, supplemental information may be provided. In some embodiments, the AI orchestrator 843 may coordinate the flow of the system 700.

The AI models 840 are shown to take a configuration 842 as input, resulting in a BOD collateral 844. The configuration 842 may include the information that the user requests to be represented in the output of the model. The configuration 842 may come from the users RFQ. The second BOD collateral 844 may be the output of the AI BOD collateral generator 845. In some embodiments, the second BOD collateral 844 may be a BOD collateral which may include at least one of BOM data, unit and wiring diagrams, unit specification text, or warranties. Equipment items may include attributes that will be used for training and generating a BOD collateral 844. The BOD collateral database 850 may be another source of input for training data. The BOD collateral database 850 may contain historical proprietary data including previous simulation engine 610 results and human generated BOD collaterals created for previous environments and buildings.

In some embodiments, the AI BOD collateral generator 845 may be configured to generate a second BOD collateral 844 including second building equipment performance ratings based on a second user request including second building equipment operating requirements, wherein the second BOD collateral 844 may be used to construct building equipment satisfying the second building equipment operating requirements. In some embodiments, the AI orchestrator 843 may be configured to determine whether to execute the simulation engine 610, or to bypass the simulation engine 610 when generating the second BOD collateral 844 based on a similarity between a second user request and one or more of the first user requests. In some embodiments, the first user request may be included in the simulation database 824, and the second user request may be included in the configuration 842 given to the AI BOD collateral generator 845 as input.

In some embodiments, the AI models 840 may be configured to generate the second BOD collateral 844 by bypassing the simulation engine 610 and reusing or modifying a portion of the first BOD collateral 612 in response to a similarity exceeding a threshold. The similarity may be between a first user request and a second user request where the first request may be stored in the simulation database 824 and the second user request may be included in the configuration 842. In some embodiments, the AI models 840 may be configured to generate the second BOD collateral 844 by executing the simulation engine 610 and discarding the first BOD collateral 612 in response to the similarity not exceeding a threshold. The threshold may be determined through training of the AI models 840 or a preset value.

In some embodiments, the AI orchestrator 843 may be configured to evaluate a similarity by comparing the second building equipment operating requirements of a second user request with the first building equipment operating requirements of the one or more of the first user requests. The second user request may be included in the configuration 842. The first user request may be included in the simulation database 824. The similarity may then be compared to a threshold. In some embodiments, the AI orchestrator 843 may be configured to evaluate a similarity by comparing a first version of the simulation engine 610 used to generate the first BOD collateral 612 with a second version of the simulation engine 610 available upon receipt of a second user request.

In some embodiments, the configuration 842 is generated from a user submitting request for quotation documents including the type of equipment required, the specification of the equipment, the building specification, etc. Request for quotation documents may further include manufacturer requirements, location requirements, environmental impact limits, etc. In some embodiments, the configuration 842 is generated by the AI interpreter 841 selecting necessary information from the user input data and collecting supplemental omitted information within the AI models 840 from the storage system 720. In some embodiments, the user input may be specifying performance requirements for the system or equipment, specifying the project details such as the number or type of equipment, specifying power requirements, specifying cooling and heating capacity, etc. The user input from the user device 710 is then interpreted into the configuration 842

The BOD collateral 844 is the result of the AI BOD collateral generator 845 generating the results from the inputted configuration 842 and supplemental data from the storage system 720 and the BOD collateral database 850. In some embodiments, the BOD collateral 844 may result from different forms of requests including prompts from a LLM, inputs from RFQ documents, and other forms of text, audio, image, and/or videos. For example, a user may provide through a conversation with an LLM requesting a chiller, then the user may provide additional information the LLM asks for including cooling tonnage, size, energy consumption, etc. The AI BOD collateral generator 845 may take the information provided in the form of a configuration 842 and generate a BOD collateral 844. The BOD collateral 844 may contain all specifications of the chiller, images of the chiller, diagrams of the building with the chiller in the building, and documents describing the reasons behind the chiller being generated as presented in the BOD collateral 844.

In some embodiments, the user inputs an image of a space in a building along with a description of the system required. For example, an 800 sq ft room may be provided in the form of an image with a description of the requirements of the room temperature being a consistent 70 degrees Fahrenheit. The configuration 842 may then be created in the form of a request for a cooling system that satisfies the request including the location of said cooling system within the room. The BOD collateral 844 may be generated as a result of the configuration 842 in the form of a bill of materials, drawings of the units and system, performance ratings of the system, warranties, etc.

In some embodiments, the user requests a system with RFQ documents missing information. For example, a user may request a system for heating and cooling a building but forgot to include information about the equipment type required for the heating system. The configuration 842 may be supplemented by the storage system 720 to include information about a heating system. The BOD collateral 844 given to the user may include information about a cooling system in the form of a bill of materials, drawings, diagrams, performance ratings, warranties, cost, etc. The heating system information will be included in the BOD collateral 844, but may include different options of systems including a different bill of materials, drawings, diagrams, performance ratings, warranties, cost, environment outcomes, etc.

Equipment items may be information on equipment items that are a part of a system to be requested by a user device 710. In some embodiments, the equipment items are generated by the AI models 840 to include information from the configuration 842 and be included in the BOD collateral 844. The equipment items may also be supplemented by the equipment database 722 to include additional information about equipment items. In some embodiments, the equipment items may include information about an equipment regarding the cooling tonnage, sq ft., airflow, static pressure, power consumption, etc. For example, a chiller may be requested through a configuration, the equipment items may include a chiller that is utilized in a 600 sq. ft. space and with a 1 kW/ton power consumption. The AI BOD collateral generator 845 may take the information and train from a simulation from the simulation engine 610 regarding the configuration 842. The equipment items information will be provided as training data to train the model to fit the chiller specifications to the current request including a space of 1000 sq. ft. and a request for a chiller with at most 1.5 kW/ton power consumption.

In some embodiments, the BOD collateral database 850 may include proprietary human-generated BOD collaterals that have specifications relating to a request from a user. The BOD collateral database 850 may store information to aid in the training of the AI BOD collateral generator 845. In some embodiments, the BOD collateral database 850 is used with the AI orchestrator 843 to check if there is an equivalent BOD collateral correlating to the configuration 842. For example, a request may be made for a chiller in a space of 1000 sq. ft. and a power consumption of 2 kW/ton. A BOD collateral from the BOD collateral database 850 may correlate directly to the request made and the BOD collateral 844 may be returned to the user device 710 without running the simulation engine 610 or generating a BOD collateral from the AI BOD collateral generator 845.

In some embodiments, generating a BOD collateral 844 includes receiving from a user a first configuration 842 comprising one or more attributes of one or more equipment items. The simulation engine 610 then searching a storage system 720 including the equipment database 722 and retrieving one or more attributes of one or more equipment items. The simulation engine 610 may then generate a first BOD collateral 612 using the configuration 842. The generating platform 702 may then train the AI BOD collateral generator 845 with the configuration 842 and the BOD collateral 612 as training data. The generating platform 702 may then use the AI BOD collateral generator 845 to generate a BOD collateral 844 based on a configuration 842 from a user device 710 provided as an input to the AI BOD collateral generator 845. Lastly, the AI BOD collateral generator 845 may then transmit the second BOD collateral 844 to the user device 710 through the communication interface 802.

In some embodiments, the first configuration 842 further comprises the one or more attributes of a project 606 related to one or more equipment items or one or more components comprising at least one of the one or more equipment items. The first configuration 842 is included in the training set to train the AI BOD collateral generator 845 to optimize outputs.

In some embodiments, a system includes a storage system 720 comprising attributes of a plurality of equipment items. The system may also include a generating platform 702. The generating platform 702 comprises a simulation engine 610 and AI models 840. The simulation engine 610 may be configured to simulate an operating performance of a first selected subset of the plurality of equipment items from the storage system 720 and generate a first BOD collateral 612 based on the simulated operating performance. The AI models 840 may be trained on the first selected subset of the plurality of equipment items and the operating performance generated by the simulation engine 610 to generate a second BOD collateral 844 based on a second selected subset of the plurality of equipment items.

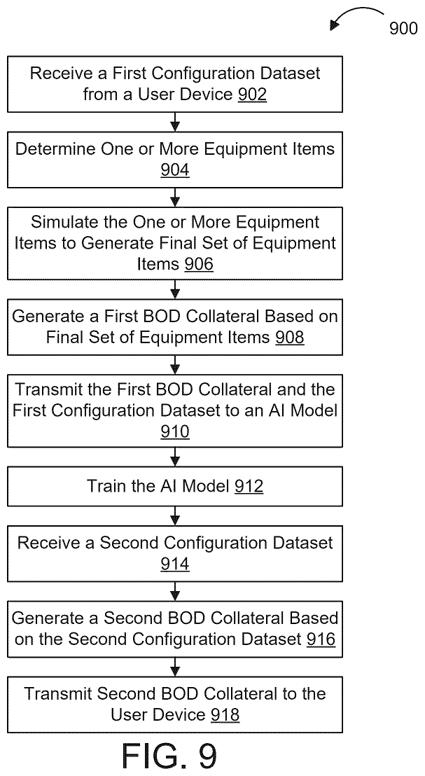

Referring now to FIG. 9 a flow chart of a process 900 of the generating platform 702 of FIG. 7 training an AI model, according to an exemplary embodiment. The process 900 includes steps for training the AI model. This process begins with receiving a first configuration dataset from a user device (step 902) which then leads to determining the one or more equipment items (step 904). The simulation of the one or more equipment items to generate the final set of equipment items (step 906) is the simulation step of the data to get part of the training data for the AI model. The next step is to generate a first BOD collateral based on the final set of equipment items (step 908). The first BOD collateral is transmitted along with the first configuration dataset to the AI model (step 910). The AI model is then trained (step 912) on the data provided to the AI model. A second configuration dataset is received (step 914) to query the AI model for a second BOD collateral. A second BOD collateral based on the second configuration dataset is generated (step 916) with the second BOD collateral being transmitted to the user device (step 918).

In some embodiments, the flow of system 800 is done by receiving, by one or more processors, a first configuration dataset (step 902) comprising one or more characteristics of one or more first equipment items (step 904). Performing by the one or more processors, a simulation using the first configuration dataset (step 906) as an input to generate a first BOD collateral (step 908) comprising a simulated performance of the one or more first equipment items. Then, training by the one or more processors, an AI model (step 912) using the first configuration dataset and the first BOD collateral as training data (step 910). Then, receiving a second configuration dataset (step 914) and using the AI model to generate a second BOD collateral based on a second configuration dataset (step 916) provided as an input to the AI model. Lastly, transmitting by the one or more processors the second BOD collateral to a user device (step 918).

In some embodiments, performing the simulation comprises determining, by the one or more processors, a first set of equipment items comprising one or more second equipment items including the one or more characteristics corresponding to at least one of the one or more characteristics of the one or more first equipment items. Then, determining, by the one or more processors, a simulated performance value of at least one of the one or more second equipment items based on the simulation of the first set of equipment items. Then, generating, by the one or more processors, a final set of equipment items (step 906) based on the simulated performance value, the final set of equipment items comprising at least one of the one or more second equipment items. Then, generating, by the one or more processors, the first BOD collateral based on the final set of equipment items (step 908). Lastly, transmitting, by the one or more processors, the first BOD collateral to the AI model (step 910).

In some embodiments, determining the first set of equipment items includes accessing, by the one or more processors, a storage system including one or more characteristics of one or more third equipment items. Then, determining, by the one or more processors, a level of similarity based on a comparison of the one or more characteristics of one or more third equipment items and the one or more characteristics of the one or more first equipment items. Then, comparing, by the one or more processors, the level of similarity to a similarity threshold. Lastly, including, by the one or more processors, a first equipment item of one or more third equipment items of the first set of equipment items, in response to the level of similarity of a first equipment item of the one or more third equipment items being greater than or equal to the similarity threshold.

In some embodiments, determining the first set of equipment items also includes determining, by the one or more processors, a first equipment item of the one or more first equipment items of the first configuration dataset, the first equipment item comprising one or more characteristics. Then, parsing, by the one or more processors, the one or more characteristics of the first equipment item of the one or more first equipment items to create a first dataset including the one or more characteristics of the first equipment item of the one or more first equipment items. Then, accessing a storage system including one or more characteristics of one or more third equipment items. Then, determining, by the one or more processors, a level of similarity based on the one or more characteristics of the first equipment item of the one or more first equipment items and the one or more characteristics of one or more third equipment items. Then, comparing, by the one or more processors, the level of similarity to a similarity threshold. Lastly, including, by the one or more processors, a first equipment item of one or more third equipment items in the first set of equipment items, in response to the level of similarity of the first equipment item of the one or more third equipment items being greater than or equal to the similarity threshold.

In some embodiments, the performance value of the at least one of the one or more second equipment items are further based on a weight associated with a manufacturer of the at least one of the one or more second equipment items. The performance value may determine the final set of equipment items.

In some embodiments, training an AI model 912 includes receiving training data including proprietary data from a BOD collateral database, manuals and documentation regarding the one or more first equipment items. Then performing, by a simulation engine, a simulation to generate supplemental training data. Then, determining, by model factors, hyperparameters to optimize the AI model. Lastly, training, by all relevant data, the AI model to generate a BOD collateral on a configuration dataset.

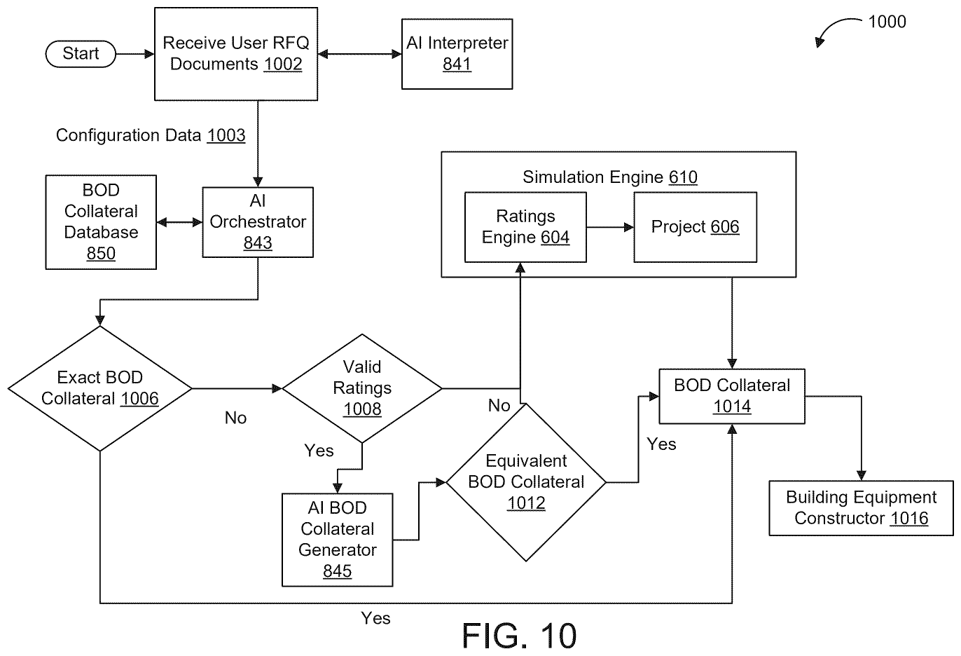

Referring now to FIG. 10, a flow chart of a process 1000 of implementing the trained AI BOD collateral generator 845 of FIG. 8 to generate BOD collaterals based on the configuration dataset is shown, according to an exemplary embodiment. The process begins with receiving user RFQ documents 1002 relating to their needs. The data provided gets communicated with an AI interpreter 841 to convert the data into configuration data 1003 and gets sent to an AI orchestrator 843. The AI orchestrator 843 communicates with the BOD collateral database 850 to analyze the existing BOD collateral data and determine if there is an exact BOD collateral (step 1006) that can be returned to the user. If there is an exact match, the BOD collateral 1014 may then feed into a building equipment constructor 1016. If there is not an exact match, the ratings engine 604 is checked for if the data is up to date. If the valid ratings (step 1008) is a yes, then the AI BOD collateral generator 845 is executed to retrieve a BOD collateral. If the BOD collateral is an equivalent BOD collateral (step 1012), then the BOD collateral 1014 may then feed into a building equipment constructor 1016. If the BOD collateral is not an equivalent configuration (step 1012), then the simulation engine 610 is executed. If the valid ratings (step 1008) is a no, then the simulation engine 610 is executed to select equipment items and generate a BOD collateral 1014 which may then feed into a building equipment constructor 1016.

The AI orchestrator 843 may incorporate the configuration data 1003 to locate the most relevant BOD collateral from the BOD collateral database 850. The BOD collateral database 850 may store information regarding BOD collaterals that reflect prior configurations. In some embodiments, the AI orchestrator 843 selects the highest correlation BOD collateral to the current configuration from the BOD collateral database 850. The AI orchestrator 843 then determines if the BOD collateral selected was an exact BOD collateral (step 1006). In some embodiments, the BOD collateral was an exact match for the configuration, and the BOD collateral 1014 is the result of the process. In some embodiments, the BOD collateral was not an exact match, and the AI orchestrator 843 continues to the valid ratings (step 1008) to check if the ratings engine 604 is up to date. An exact BOD collateral (step 1006) is determined by the AI orchestrator 843 by comparing the specification and configuration correlating to the BOD collateral selected and the current configuration and equipment specifications.

The AI BOD collateral generator 845 may be executed upon the valid ratings (step 1008) being a yes. In some embodiments, the AI BOD collateral generator 845 may be trained on data from the simulation engine 610 and BOD collaterals from the BOD collateral database 850. The AI BOD collateral generator 845 may be executed to generate a BOD collateral that matches the configuration provided from the user and through the AI orchestrator 843. The outputted BOD collateral is then compared to see if it has an equivalent BOD collateral (step 1012) to the configuration provided. For example, if the BOD collateral is equivalent, the BOD collateral 1014 may then feed into a building equipment constructor 1016. Another example if the BOD collateral is not equivalent, the simulation engine 610 is executed to generate a BOD collateral 1014 that may then feed into a building equipment constructor 1016. In some embodiments, the valid ratings (step 1008) step is a no, and the simulation engine 610 is executed to generate a BOD collateral 1014 that may then feed into a building equipment constructor 1016.

In some embodiments, generating the first configuration dataset includes receiving the RFQ documentation 1002 and performing by an AI interpreter 841 model an extraction of configuration data 1003. The AI interpreter 841 model converts the documentation into a first configuration dataset.

In some embodiments, generating the second BOD collateral includes determining by a BOD collateral database 850, there is not an exact BOD collateral (step 1006) match and determining the ratings engine 604 is up to date, meaning the valid ratings (step 1008) is true. And generating the second BOD collateral based on a configuration dataset provided as input to the AI BOD collateral generator 845.

In some embodiments, the building equipment constructor 1016 may construct building equipment satisfying a building equipment operating requirements. The building equipment constructor 1016 may take a BOD collateral 1014 to construct building equipment satisfying building equipment operating requirements. In some embodiments, the BOD collateral 1014 may be generated from a simulation engine 610. In some embodiments, the BOD collateral may be generated by the AI BOD collateral generator 845. In some embodiments, the BOD collateral 1014 may be a BOD collateral from the BOD collateral database 850.

In some embodiments, determining whether to execute the simulation engine 610 or bypass the simulation engine 610 when generating the second BOD collateral 1014 may be based on a similarity between a second user request and one or more first user requests. In some embodiments, generating the second BOD collateral 1014 by bypassing the simulation engine 610 and reusing or modifying a portion of the first BOD collateral may be in response to a similarity exceeding a threshold which may be an exact BOD collateral (step 1006). In some embodiments, determining whether to execute the simulation engine 610 may include generating the second BOD collateral 1014 by executing the simulation engine 610 and discarding a first BOD collateral in response to the similarity not exceeding a threshold to be an exact BOD collateral (step 1006).

In some embodiments, determining whether to execute the simulation engine 610 or bypass the simulation engine 610 when generating the second BOD collateral 1014 may include evaluating the similarity by comparing a second building equipment operating requirements of a second user request with the first building equipment operating requirements of one or more first user requests to determine if there may be an exact BOD collateral (step 1006). In some embodiments, determining whether to execute the simulation engine 610 or bypass the simulation engine 610 when generating the second BOD collateral 1014 may include evaluating the similarity by comparing a first version of the simulation engine 610 used to generate a first BOD collateral with a second version of the simulation engine 610 available upon receipt of a second user request.

In some embodiments, one or more non-transitory computer readable media storing instructions that may be executed by one or more processors may then cause the one or more processors to perform operations included within system 1000. The execution of said instructions by said one or more processors may include determining whether to execute the simulation engine 610 or bypass the simulation engine 610 when generating the second BOD collateral 1014.

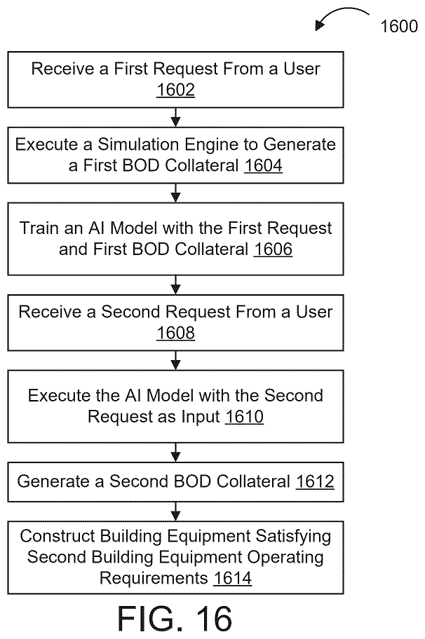

Referring now to FIG. 16, a flow chart of a process of the generating platform of FIG. 7 training and executing the AI model, according to an exemplary embodiment. In some embodiments, the process 1600 may include receiving a first request from a user (step 1602). The process 1600 may then include executing the simulation engine to generate a first BOD collateral (step 1604) which may include first simulated building equipment performance ratings based on first user requests comprising first building equipment operating requirements. The process 1600 may then train an AI model with the first request and first BOD collateral (step 1606) as training data. The process 1600 may then receive a second request from a user (step 1608). The process 1600 may then execute the AI model with the second request as input (step 1610) to generate a second BOD collateral (step 1612) which may include second building equipment performance ratings based on a second user request including second building equipment operating requirements. The process 1600 may then use the second BOD collateral to construct building equipment satisfying second building equipment operating requirements (step 1614). In some embodiments, a first BOD collateral and a second BOD collateral may include at least one of BOM data, unit and wiring diagrams, unit specification text, or warranties.

### BOD Collateral Examples

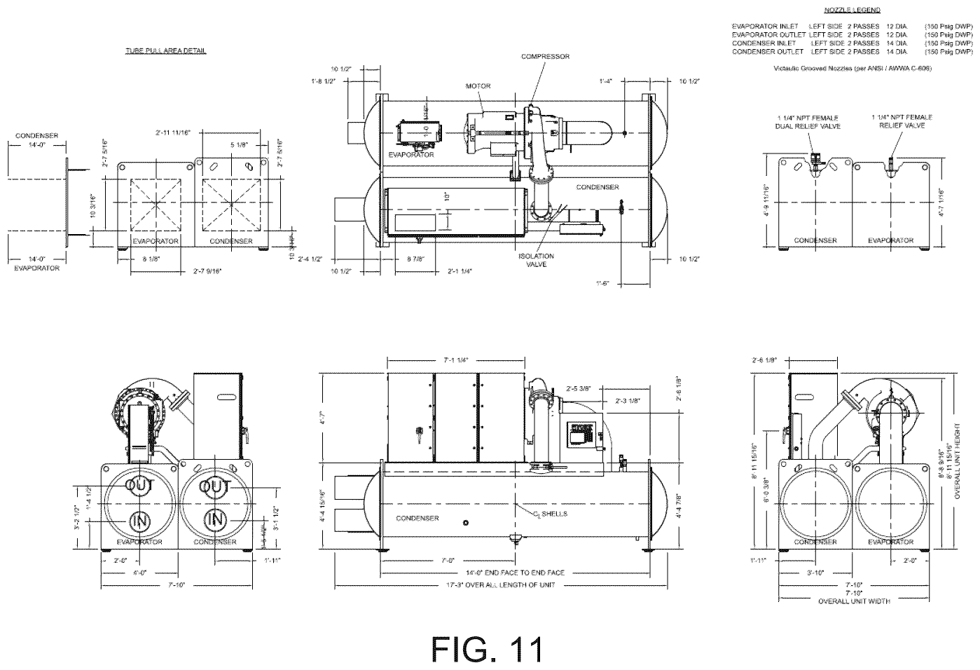

Referring now to FIGS. 11-15B, several examples of BOD collateral (e.g., BOD collateral 612, BOD collateral 1014) which can be generated and used by the systems and methods of the present disclosure are shown, according to an exemplary embodiment. As described above, BOD collateral can be generated by various components of generating platform 702. For example, some BOD collateral can be generated by simulation engine 610 running simulations (e.g., equipment ratings, performance simulations, etc.) in response to user requests (e.g., user requests for quotations) as shown in FIG. 10. The BOD collateral generated by simulation engine 610 and the corresponding user requests can be used as training data for an AI model (e.g., AI BOD collateral generator 845). For example, the AI BOD collateral generator 845 can be trained to generate BOD collateral that corresponds to the user requests, learning from the output of simulation engine 610. Once trained, the AI model can then be executed to automatically generate new BOD collateral (e.g., as outputs of the AI model) upon receipt of new user requests, without requiring simulation engine 610 to be executed again in response to the new user requests. In this way, the AI model streamlines the process of generating BOD collateral and improves upon conventional systems which rely on running new simulations for every user request.

As described above, BOD collateral may include a variety of different types of information pertinent to the design, configuration, construction, operation, and/or performance of building equipment. For example, a user may submit a request indicating a desired performance or other requirements for a hypothetical unit or system of building equipment the user wishes to add to a building (e.g., “I need a chiller that provides X tons of cooling, consumes less than Y units of power, and connects to the other equipment in my plant”). The BOD collateral generated in response to the user request may include a complete specification of a unit of building equipment or system of building equipment that meets the user's requirements along with a variety of pertinent information relating to the equipment's components, configuration, simulated performance, connections to other equipment, etc. The BOD collateral may identify specific units or models of building equipment that already exist (e.g., equipment currently for sale from a vendor) and/or new hypothetical building equipment that does not yet exist but could be constructed to meet the user's requirements.

In some embodiments, BOD collateral can be generated and presented to the user in the form of a report (e.g., a PDF file, a webpage, a word document, etc.) which includes a variety of sections describing the design and construction of building equipment that meets the user's requirements. For example, a BOD collateral report may include a bill of materials (BOM) data section, a unit and wiring drawings section, a unit specifications text section, a performance ratings section, and a warranties section, and/or other types of information that provide the user with an informed breakdown of the specific units of building equipment and their respective ratings and attributes that could be constructed to meet the user's requirements. Several examples of the types of information and content that can be included in each of these sections of the BOD collateral are described in greater detail below. Although the specific examples provided below are for a chiller, it is contemplated that BOD collateral can be generated for any type of HVAC equipment (e.g., pumps, valves, air handling units, fans, variable refrigerant flow systems, boilers, etc.) and/or any other type of building equipment (e.g., security equipment, lighting equipment, networking equipment, data center equipment, etc.) in various embodiments.

### Bill of Material (BOM) Data

BOD collateral may include a BOM, according to some embodiments. In general, a BOM identifies one or more specific items of building equipment or components (e.g., specific chiller models, valve models, flow sensor models, etc.) that can be combined to form a system or device that meets the user's requirements. A BOM may include information corresponding to the bid date, project, party of interest, addendums, equipment's, equipment descriptions, and equipment proposals. The bid date may correlate to the date the user expects to receive the information regarding the system design. The project may correlate to the project name. The party of interest may correlate to the user making a request. The addendums may correlate to any adjustments to the BOD collateral. The equipment's may correlate to the designed equipment's that are required for the requested system. The equipment descriptions may correlate to the designed equipment's and may include the equipment proposal which may include the specific hardware of said equipment's.

The equipment's section may include one or more equipment items that are a part of the system requested, in some embodiments. The equipment items may include an item ID, a quantity, tags, and a description. An item ID may correlate to the identification of an item. For example, an item ID may be “I”. A quantity of an equipment item may correlate to the number of said equipment item required for the system requested. For example, a quantity of an equipment item may be 1. Tags may correlate to the type of equipment item or the use of said equipment item. For example, a tag may be “(1)CH-2”. A description may correlate to the name of an equipment item. For example, a description may be “Water-Cooled Centrifugal Chiller”.

The equipment descriptions section may include an equipment proposal section, in some embodiments. The equipment proposal section may include items for equipment items required for the system. In some embodiments, the list of said items may include different sections for different sources of said items. The list of said items may include models, motors, valves, evaporators, sensors, condensers, boards, switches, piping, wiring, etc. including a quantity of an item. For example, an equipment proposal may include a list of items including: Provide Model YMC2-S3165AB Qty: 1; Motor, 400 volts, 3 phase, 50 Hz; Motor Enclosure: Hermetically Sealed; Isolation Valves; Evaporator; Compact Water Boxes, rated for 150 [10.3] psig water-side pressure; Evaporator Grooved Nozzles Connection; Evaporator Tube R-1215.025 Wall MT #656; 2 Passes; Flow Sensors, factory mounted and wired; Condenser; Compact Water Boxes, rated for 150 [10.3] psig water-side pressure; Condenser Grooved Nozzles Connection; Condenser Tube R-1213 .025 Wall MT #496; 2 Passes; Flow Sensors, factory mounted and wired; Unit Warranty: 18 Month (1 Year) (Std) Entire Unit Parts Only (from date of shipment); Complete Chiller Bagging; Smart Equipment Board; Chiller Start up (PCAT); Shipment Form 01; 1″ Thick Neoprene Pad; Evaporator Thermal Switch; Condenser Thermal Switch; Evaporator Insulation; Refrigerant monitor or SCBA; Rigging, hauling, or providing access for equipment; Valves for vents and drains; Pressure gauges for chilled water lines; Relief piping to the atmosphere; Disassembly/Reassembly of chiller if required for installation; Coordination drawings of central plant; Occupancy adjustments after completion of York's chiller start-up; and Piping and Wiring. In some embodiments, the items list corresponds to one or more equipment items.

### Unit and Wiring Diagrams

A BOD collateral may include unit and wiring drawings, according to some embodiments. The unit and wiring diagrams may include engineering drawings of the building equipment (e.g., top view, side views, bottom view, perspective view, etc.) or other items included in the BOD collateral (e.g., floor layouts) along with dimensions and descriptive text labels. Wiring diagrams may indicate how to wire or connect the building equipment to power sources and/or other building equipment (e.g., controller-device connections, communications bus connections, data connections, power connections, etc.). The unit and wiring drawings section may include a product type, unit tags, product drawings, wiring diagrams, and general safety guidelines. The product type may describe the type of a unit. The unit tags may be a tag applied to the unit.

In some embodiments, product drawings may show a unit and all of the unit's parts. The product drawings may also show the floor layout and other environments of the unit. The product drawings may show the inner workings of said unit including each part of the unit. In some embodiments, the product drawings may also include a heaviest component, an operating weight, a load per isolator, and shipping weights of the unit. The product drawings may also include measurements of each component of the unit. The product drawings may also include a legend describing parts of a drawing.

Referring to FIG. 11, a product drawing of a water-cooled chiller which can be generated as a type of BOD collateral by the generating platform of FIG. 7, according to an exemplary embodiment. In some embodiments, the product drawing may show a water-cooled chiller from a top view, a side view, a front view, and a back view. The views may contain dimensions of said water-cooled chiller. A product drawing may be included in a BOD collateral. A product drawing may be included in a unit and wiring diagrams section of a BOD collateral.

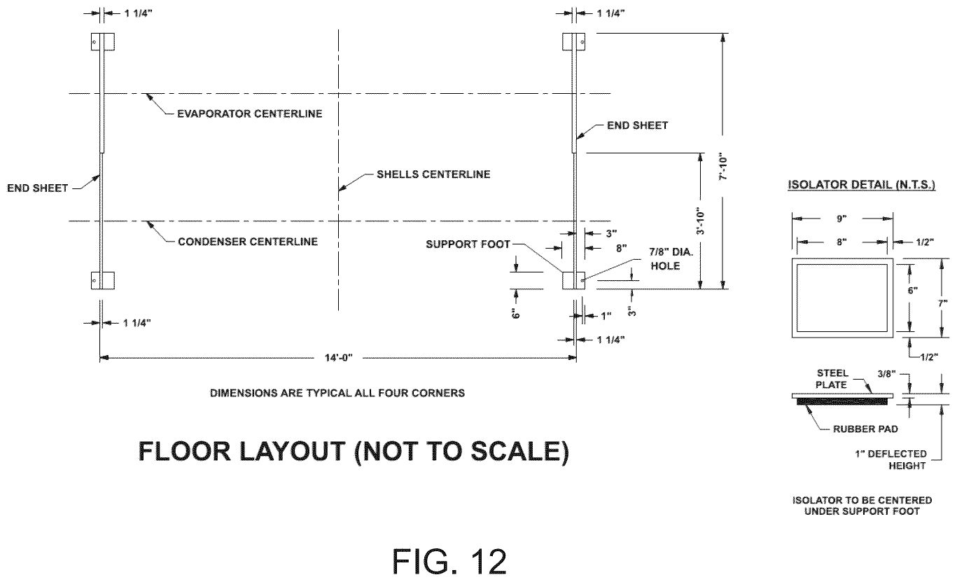

Referring to FIG. 12, a product drawing of a water-cooled chiller surroundings which can be generated as a type of BOD collateral by the generating platform of FIG. 7, according to an exemplary embodiment. In some embodiments, the product drawing may show a water-cooled chiller environment including a floor layout and an isolator detail. A product drawing may be included in a BOD collateral. A product drawing may be included in a unit and wiring diagrams section of a BOD collateral.

For example, a unit and wiring drawings may have a product type of “YMC2—Water-Cooled Chiller” and a unit tag of “CH-2”. The unit and wiring drawings may have product drawings that include a top view, side views, a bottom view, and views of individual components including an evaporator and condenser of the Water-Cooled Chiller. Each view of the Water-Cooled Chiller may include measurements of each component and the layout of each component. The product drawing may include labels for an evaporator, a condenser, a motor, and an isolation valve. The product drawing may include measurements for each of said components including an overall unit width, length and height of the unit. The product drawings may include a product drawing including a floor layout and isolator details. The floor layout may include dimensions of the floor, objects within the floor, locations of support, a condenser centerline, an evaporator centerline, etc. The isolator detail may include isolator dimensions, a steel plate with dimensions, and a rubber pad with dimensions.

In some embodiments, the unit and wiring drawings may include general safety guidelines. The general safety guidelines may provide information regarding the potential dangers of a unit and how to mitigate risks. The general safety guidelines may also include safety symbols indicating the type of hazards found included with the unit.

In some embodiments, the unit and wiring drawings may include wiring drawings. The wiring drawings may include a list of figures. The wiring drawings may include notes directed towards the wiring of the unit. The wiring drawings may include tables and figures representing different values and use cases of the unit.

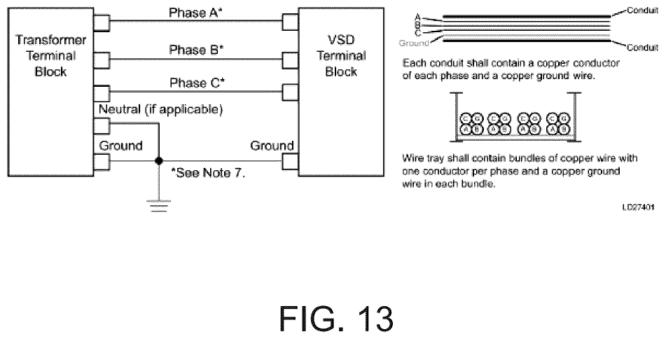

Referring to FIG. 13, a wiring drawing of a grounding variable speed drive which can be generated as a type of BOD collateral by the generating platform of FIG. 7, according to an exemplary embodiment. In some embodiments, the wiring drawing of a grounding variable speed drive may be included in a BOD collateral. A wiring drawing may be included in a unit and wiring diagrams section of a BOD collateral.

For example, the wiring drawings may include notes about codes relating to the wiring, warnings for proper grounding, control power supply specification, etc. The wiring drawings may also include tables including lug details, conduit details, and voltage ranges. The wiring drawings may include figures including for a grounding variable speed drive (VSD). The figures may include different views of the VSD including a top view, side view, front view, bottom view, etc. The figures may include information of the VSD including dimensions, voltage levels, and wiring layouts.

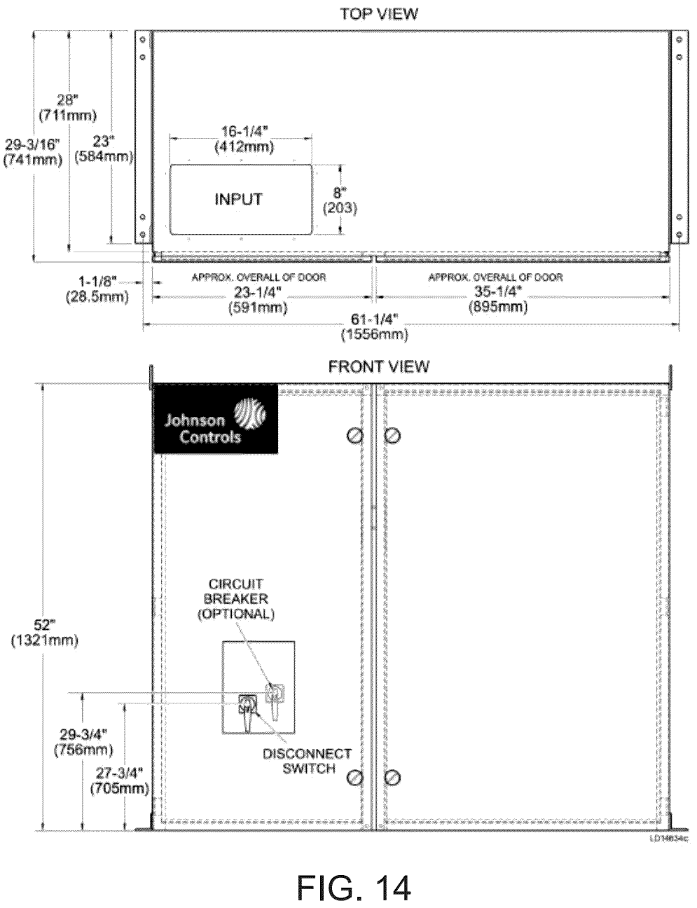

Referring to FIG. 14, a drawing of a variable speed drive which can be generated as a type of BOD collateral by the generating platform of FIG. 7, according to an exemplary embodiment. In some embodiments, a drawing of a variable speed drive may be included in a BOD collateral. A drawing of a variable speed drive may be included in a unit and wiring diagrams section of a BOD collateral.

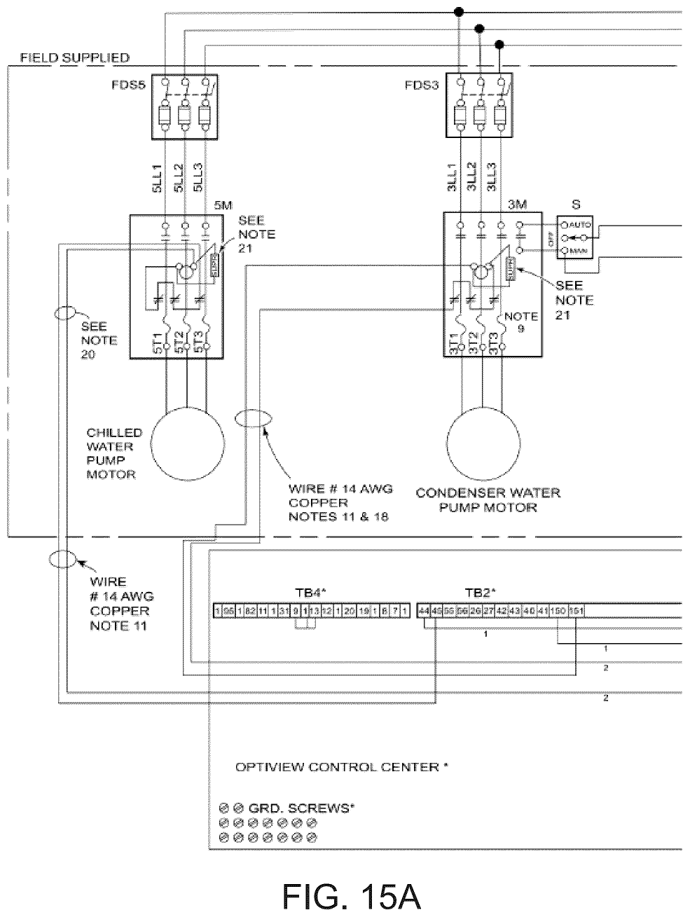

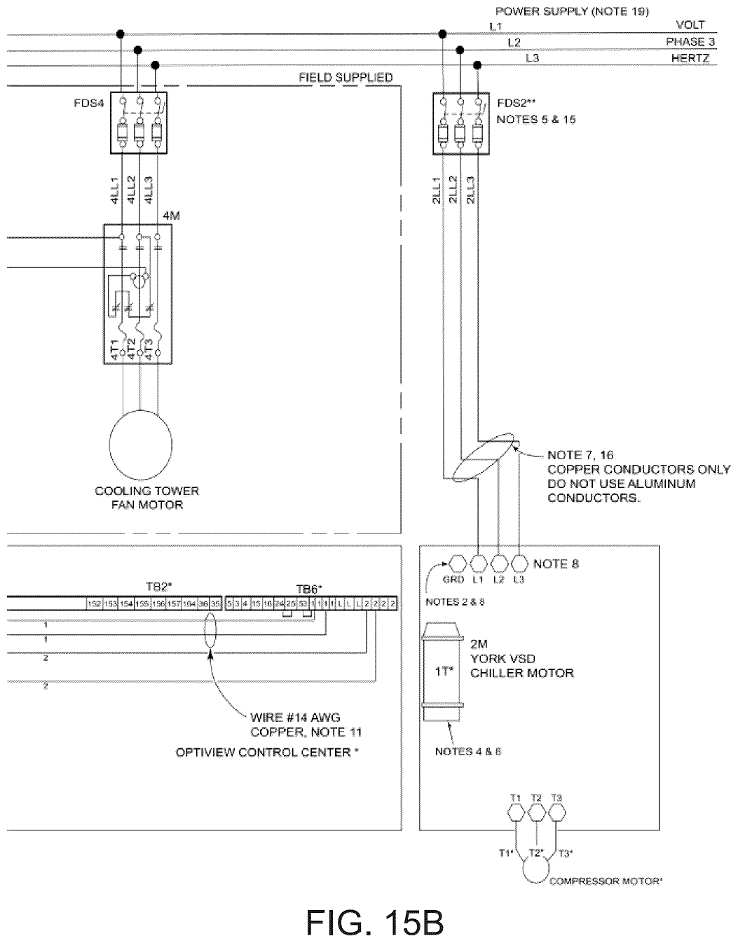

Referring to FIG. 15A and FIG. 15B, a drawing of field connections which can be generated as a type of BOD collateral by the generating platform of FIG. 7, according to an exemplary embodiment. In some embodiments, field connections may be the wiring between a unit and a power source. In some embodiments, a drawing of field connections may be included in a BOD collateral. A drawing of field connections may be included in a unit and wiring diagrams section of a BOD collateral.

### Specifications Text

A BOD collateral may include unit specifications text, according to some embodiments. The unit specifications text may include a detailed breakdown of the specific unit of building equipment or set of building equipment described in the BOD collateral along with its various attributes. Unit specifications text may include descriptions of a unit with sections including general, products and execution. Each section may have one or more subsections. Each subsection may further explain an aspect of the unit. In some embodiments, the general section may include references, quality assurance, ratings and certifications, submittal documentation required, shipment, delivery, storage and handling, warranty, and maintenance. The products section may include information specific to the unit. The execution section may include information including installation, field quality control, startup service, owner instruction, cleaning, and documentation.

In some embodiments, the products section may include sections for acceptable manufacturers, general description, heat exchangers, refrigerant flow control, compressor, motor, lubrication system (for non-magnetic bearing chiller designs), refrigerant purge system (negative pressure machines), positive pressure system (negative pressure machines), source quality control: tests and inspections, control panel, compressor motor starter: variable speed drive, finishes, options, accessories, and verification of performance. Each section may include information correlating to the unit.

For example, a Water-Cooled Centrifugal Chiller may have unit specifications text with sections including general, products, and execution. The general section may include information about the centrifugal compressor water chillers, water connections, motor starters and variable frequency drives, electrical connections, controls and control accessories, charge of refrigerant and oil, and refrigerant purge system and positive pressure system. The general section may also include information on related sections and references. The general section may also include information on manufacturers, and codes and standard. The general section may also include information on chiller rating and testing, chiller energy efficiency requirements, safety, motor manufacturing and performance, pressure vessel construction and testing, electrical and control wiring, and refrigeration system design, construction, and installation and operation. The general section may also include information on acoustics. The general section may also include information on shipping instructions including protect, pack and secure loose-shipped items and attach to chiller, cap and seal water nozzle openings, provide reinforced shrink-wrap around entire exterior of the chiller, ship chiller in one major assembly, and ship refrigerant in the condenser barrel of the chiller. The general section may also include information on warranty coverage and lengths.

The products section may include information on a heat exchange of a condenser and evaporator. The products section may also include information on lubrication including an oil reservoir, pump, filter, return system, cooler, heater, temperature, pump operation, and means of lubrication after power failure. The products section may include further information about the unit. The execution section may include information about the installation specific to the unit.

### Performance Ratings

A BOD collateral may include a performance ratings section, according to some embodiments. The performance ratings may include various information that indicates how the building equipment described in the BOD collateral would perform during operation. In some embodiments, the information included in the performance ratings section of the BOD collateral can be generated by simulation engine 610 and/or by an AI model trained based on the outputs of simulation engine 610. The performance ratings section may include a product type, unit tags, and a performance report. The product type may describe the type of a unit. The unit tags may be a tag applied to the unit.

In some embodiments, the performance report includes sections including unit, performance data, electrical data, performance impacting options, weight and dimensional data, heat exchanger performance, part load performance, sound pressure levels, unit configuration details, weight breakdown details, and warnings.

For example, the performance ratings may have a product type of “YMC2—Water-Cooled Chiller” and a unit tag of “CH-2”. The performance report may have a unit section with information including model number, number of compressors, compressor type, number of compressor circuits, refrigerant, compressor, and variable orifice. The performance report may have a performance data section with information including specified net capacity, rated net capacity, full load efficiency, part load efficiency, heat rejection capacity, and a-weighted sound pressure level. The performance report may have an electrical data section with information including power supply, total input power, minimum circuit ampacity, maximum circuit breaker amps, and job FLA.

The performance report may have a performance impaction options section with information including starter type, starter model, isolation valves, and optisound control. The performance report may have a weight and dimensional data section with information including shipping weight, operating weight, refrigerant weight, length, width, and height. The performance report may have a heat exchanger performance section with information including model, fluid type, tube MTI number, passes, fouling factor, entering fluid temperature, leaving fluid temperature, flow rate, and pressure drop. The performance report may have a part load performance section with information including percent load, net capacity, input power, evaporator EFT, evaporator LFT, condenser EFT, condenser LFT, and efficiency.

The performance report may have a sound pressure levels section with information including percent load, octave band center frequency, and a-weighted dBa. The performance report may have a unit configuration details section with information including water box type, waterside design working pressure, entering water nozzle, leaving water nozzle, water box weight, cover plate weight, return head weight, and water weight. The performance report may have a weight breakdown details section with information including operating weight, refrigerant weight, compressor weight, and shipping weight.

### Warranty Data

A BOD collateral may include a warranties section, according to some embodiments. The warranties section may include various information pertaining to warranties that apply to the building equipment described in the BOD collateral. The warranties may include standard warranties from the equipment manufacturer, vendor, or installer of the building equipment. For example, the warranties may pertain to the parts of the building equipment, labor of the installer, or other services provided by the vendor or installer. The warranties section may include a product type, unit tags, a certificate of limited warranty, a standard limited warranty engineered systems equipment form, and an equipment release approval form. The product type may describe the type of a unit. The unit tags may be a tag applied to the unit.

In some embodiments, the certificate of limited warranty may include a policy statement, exclusions, and a void warranty section. The standard limited warranty engineered systems equipment form may include a policy statement, exclusions, and a void warranty section. The equipment release approval form may include submittal notes, submittal verification, and delivery information.

For example, the certificate of limited warranty may include a policy statement that describes the conditions of the policy including the warranty type which may be a standard, entire unit, parts only warranty with a 1-year duration and no expiration date. The expiration data may be dependent on the date of start-up, or a ship date. the certificate of limited warranty may include a exclusions which may include information on the warranty not including costs and expenses related to labor to repair, remove, or reinstall any equipment, materials, or components, special shipping, handling, or transportation charges, including cranes, safety walks or other safety requirements specific to jobsites, cost of refrigerant, freight damage, field applied coatings added to any surface or heat exchanger, retail chillers, and normal wear and tera or corrosion.

The certificate of limited warranty may include a void warranty section with reasons a warranty may be void including use of unauthorized refrigerants, oil, additives, or antifreeze agents, use of any material or equipment not approved by supplying factory, equipment damaged by freezing because it was not properly protected, equipment is not applied, installed, operated, maintained and serviced in accordance with instructions, equipment is damaged due to dirt, air, moisture, or other foreign matter entering the refrigerant system, etc. The standard limited warranty engineered systems equipment form may include additional information on the exclusions and requirements for a void warranty. The equipment release approval form may include a submittal verification table with checks for quality assurance. The table may include electrical voltage and electrical connections, piping and ductwork, unit tag designations, equipment dimensions, unit hand, and equipment configuration details. The equipment release approval form may include a delivery information table. The delivery information table may include contact names, contact phone number, advance notice to a delivery company, an address, and other special shipping instructions.

### Configuration of Exemplary Embodiments

The construction and arrangement of the systems and methods as shown in the various exemplary embodiments are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.). For example, the position of elements may be reversed or otherwise varied and the nature or number of discrete elements or positions may be altered or varied. Accordingly, all such modifications are intended to be included within the scope of the present disclosure. The order or sequence of any process or method steps may be varied or re-sequenced according to alternative embodiments. Other substitutions, modifications, changes, and omissions may be made in the design, operating conditions and arrangement of the exemplary embodiments without departing from the scope of the present disclosure.

The present disclosure contemplates methods, systems and program products on any machine-readable media for accomplishing various operations. The embodiments of the present disclosure may be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. When information is transferred or provided over a network or another communications connection (either hardwired, wireless, or a combination of hardwired or wireless) to a machine, the machine properly views the connection as a machine-readable medium. Thus, any such connection is properly termed a machine-readable medium. Combinations of the above are also included within the scope of machine-readable media. Machine-executable instructions include, for example, instructions and data which cause a general purpose computer, special purpose computer, or special purpose processing machines to perform a certain function or group of functions.

Although the figures show a specific order of method steps, the order of the steps may differ from what is depicted. Also two or more steps may be performed concurrently or with partial concurrence. Such variation will depend on the software and hardware systems chosen and on designer choice. All such variations are within the scope of the disclosure. Likewise, software implementations could be accomplished with standard programming techniques with rule based logic and other logic to accomplish the various connection steps, processing steps, comparison steps and decision steps.

In various implementations, the steps and operations described herein may be performed on one processor or in a combination of two or more processors. For example, in some implementations, the various operations could be performed in a central server or set of central servers configured to receive data from one or more devices (e.g., edge computing devices/controllers) and perform the operations. In some implementations, the operations may be performed by one or more local controllers or computing devices (e.g., edge devices), such as controllers dedicated to and/or located within a particular building or portion of a building. In some implementations, the operations may be performed by a combination of one or more central or offsite computing devices/servers and one or more local controllers/computing devices. All such implementations are contemplated within the scope of the present disclosure. Further, unless otherwise indicated, when the present disclosure refers to one or more computer-readable storage media and/or one or more controllers, such computer-readable storage media and/or one or more controllers may be implemented as one or more central servers, one or more local controllers or computing devices (e.g., edge devices), any combination thereof, or any other combination of storage media and/or controllers regardless of the location of such devices.

What is claimed is:

1. A building equipment construction system comprising:
a simulation engine configured to generate first basis of design (BOD) collateral comprising first simulated building equipment performance ratings based on first user requests comprising first building equipment operating requirements; and
an artificial intelligence (AI) model trained on the first user requests and the first BOD collateral and configured to generate second BOD collateral comprising second building equipment performance ratings based on a second user request comprising second building equipment operating requirements, wherein the second BOD collateral is used to construct building equipment satisfying the second building equipment operating requirements.

2. The building equipment construction system of claim 1, wherein the first BOD collateral and the second BOD collateral further comprise at least one of bill of material (BOM) data, unit and wiring diagrams, unit specification text, or warranties.

3. The building equipment construction system of claim 1, wherein the AI model is configured to determine whether to execute the simulation engine or bypass the simulation engine when generating the second BOD collateral based on a similarity between the second user request and one or more of the first user requests.

4. The building equipment construction system of claim 3, wherein the AI model is configured to generate the second BOD collateral by bypassing the simulation engine and reusing or modifying a portion of the first BOD collateral in response to the similarity exceeding a threshold.

5. The building equipment construction system of claim 3, wherein the AI model is configured to generate the second BOD collateral by executing the simulation engine and discarding the first BOD collateral in response to the similarity not exceeding a threshold.

6. The building equipment construction system of claim 3, wherein the AI model is configured to evaluate the similarity by comparing the second building equipment operating requirements of the second user request with the first building equipment operating requirements of the one or more of the first user requests.

7. The building equipment construction system of claim 3, wherein the AI model is configured to evaluate the similarity by comparing a first version of the simulation engine used to generate the first BOD collateral with a second version of the simulation engine available upon receipt of the second user request.

8. A method for simulating and constructing building equipment, comprising:
executing a simulation engine to generate first basis of design (BOD) collateral comprising first simulated building equipment performance ratings based on first user requests comprising first building equipment operating requirements;
training an artificial intelligence (AI) model using the first user requests and the first BOD collateral as training data;
executing the AI model to generate second BOD collateral comprising second building equipment performance ratings based on a second user request comprising second building equipment operating requirements; and
using the second BOD collateral to construct building equipment satisfying the second building equipment operating requirements.

9. The method of claim 8, wherein the first BOD collateral and the second BOD collateral further comprise at least one of bill of material (BOM) data, unit and wiring diagrams, unit specification text, or warranties.

10. The method of claim 8, comprising determining whether to execute the simulation engine or bypass the simulation engine when generating the second BOD collateral based on a similarity between the second user request and one or more of the first user requests.

11. The method of claim 10, comprising generating the second BOD collateral by bypassing the simulation engine and reusing or modifying a portion of the first BOD collateral in response to the similarity exceeding a threshold.

12. The method of claim 10, comprising generating the second BOD collateral by executing the simulation engine and discarding the first BOD collateral in response to the similarity not exceeding a threshold.

13. The method of claim 10, comprising evaluating the similarity by comparing the second building equipment operating requirements of the second user request with the first building equipment operating requirements of the one or more of the first user requests.

14. The method of claim 10, comprising evaluating the similarity by comparing a first version of the simulation engine used to generate the first BOD collateral with a second version of the simulation engine available upon receipt of the second user request.

15. One or more non-transitory computer-readable media storing instructions that, when executed by one or more processors, cause the one or more processors to perform operations comprising:
executing a simulation engine to generate first basis of design (BOD) collateral comprising first simulated building equipment performance ratings based on first user requests comprising first building equipment operating requirements;
training an artificial intelligence (AI) model using the first user requests and the first BOD collateral as training data;
executing the AI model to generate second BOD collateral comprising second building equipment performance ratings based on a second user request comprising second building equipment operating requirements; and
using the second BOD collateral to construct building equipment satisfying the second building equipment operating requirements.

16. The one or more non-transitory computer-readable media of claim 15, wherein the first BOD collateral and the second BOD collateral further comprise at least one of bill of material (BOM) data, unit and wiring diagrams, unit specification text, or warranties.

17. The one or more non-transitory computer-readable media of claim 15, the operations comprising determining whether to execute the simulation engine or bypass the simulation engine when generating the second BOD collateral based on a similarity between the second user request and one or more of the first user requests.

18. The one or more non-transitory computer-readable media of claim 17, the operations comprising generating the second BOD collateral by bypassing the simulation engine and reusing or modifying a portion of the first BOD collateral in response to the similarity exceeding a threshold.

19. The one or more non-transitory computer-readable media of claim 17, the operations comprising generating the second BOD collateral by executing the simulation engine and discarding the first BOD collateral in response to the similarity not exceeding a threshold.

20. The one or more non-transitory computer-readable media of claim 17, the operations comprising evaluating the similarity by comparing at least one of:
the second building equipment operating requirements of the second user request with the first building equipment operating requirements of the one or more of the first user requests; or
a first version of the simulation engine used to generate the first BOD collateral with a second version of the simulation engine available upon receipt of the second user request.
